(19) United States
(12) Patent Application Publication
(10) Pub. No.: US 2026/0143795 A1
(43) Pub. Date: May 21, 2026

(54) SEMICONDUCTOR DEVICE INCLUDING TRANSISTORS

(71) Applicant: Samsung Electronics Co., Ltd., Suwon-si (KR)

(72) Inventors: Jongyong Son, Suwon-si (KR); Minhyung Kang, Suwon-si (KR); Jiyeon Kwon, Suwon-si (KR); Minjae Kim, Suwon-si (KR); Juyoun Kim, Suwon-si (KR); Jongsang Oh, Suwon-si (KR); Hyungjong Lee, Suwon-si (KR)

(21) Appl. No.: 19/203,392

(22) Filed: May 9, 2025

(30) Foreign Application Priority Data
Nov. 19, 2024 (KR) 10-2024-0164868

(51) Int. Cl. H10D 84/83; H10D 84/01

(52) U.S. Cl. CPC H10D 84/832; H10D 84/013; H10D 84/0149

(57) ABSTRACT

Provided is a semiconductor device. The semiconductor device includes first and second NMOS transistor structures. The first NMOS transistor structure includes a first NMOS source/drain region, first NMOS channel layers, and a first NMOS gate electrode, a first NMOS gate dielectric layer, and a first NMOS insulating spacer structure between the first NMOS gate dielectric layer and the first NMOS source/drain region. The second NMOS transistor structure includes a second NMOS source/drain region, second NMOS channel layers, a second NMOS gate electrode, a second NMOS gate dielectric layer, and a second NMOS insulating spacer structure between the second NMOS gate dielectric layer and the second NMOS source/drain region. The first NMOS insulating spacer structure includes an insulating spacer pattern, and the second NMOS insulating spacer structure includes an insulating oxide layer and does not include an insulating spacer pattern identical to the insulating spacer pattern.

### CROSS-REFERENCE TO RELATED APPLICATION(S)

This application claims benefit of priority to Korean Patent Application No. 10-2024-0164868, filed on Nov. 19, 2024, in the Korean Intellectual Property Office, the disclosure of which is incorporated herein by reference in its entirety.

### BACKGROUND

The present disclosure relates to semiconductor device including transistors and a forming method thereof.

With an increase in demand for high performance, high speed, and/or multi-functionality of semiconductor devices, the integration of semiconductor devices has increased. To manufacture semiconductor devices having fine patterns in response to the trend toward high integration of semiconductor devices, it may be important to implement patterns having fine widths or fine separation distances. In addition, efforts have been made to develop semiconductor devices including transistors having a three-dimensional channel structure To overcome the limitations of operating characteristics due to the size reduction of planar metal oxide semiconductor FETs (MOSFETs).

### SUMMARY

Embodiments of the present disclosure is provide a semiconductor device that may increase integration.

Embodiments of the present disclosure is provide a semiconductor device that may improve performance.

Embodiments of the present disclosure to provide a forming method of the semiconductor device.

Provided is a semiconductor device according to an example embodiment of the technical concept of the present disclosure. The semiconductor device includes: a first NMOS transistor structure; and a second NMOS transistor structure. The first NMOS transistor structure includes: a first NMOS source/drain region; first NMOS channel layers stacked and spaced apart from each other, and electrically connected to the first NMOS source/drain region in a first direction; a first NMOS gate electrode surrounding each of the first NMOS channel layers in a second direction, crossing the first direction; a first NMOS gate dielectric layer between the first NMOS gate electrode and the first NMOS channel layers, and between the first NMOS gate electrode and the first NMOS source/drain region; and a first NMOS insulating spacer structure between the first NMOS gate dielectric layer and the first NMOS source/drain region. The second NMOS transistor structure includes: a second NMOS source/drain region; second NMOS channel layers stacked and spaced apart from each other, and electrically connected to the second NMOS source/drain region in the first direction; a second NMOS gate electrode extending in the second direction, and surrounding each of the second NMOS channel layers in the second direction; a second NMOS gate dielectric layer between the second NMOS gate electrode and the second NMOS channel layers, and between the second NMOS gate electrode and the second NMOS source/drain region; and a second NMOS insulating spacer structure between the second NMOS gate dielectric layer and the second NMOS source/drain region. The first NMOS insulating spacer structure includes a first NMOS insulating spacer pattern, and the second NMOS insulating spacer structure includes a second NMOS insulating oxide layer and does not include an insulating spacer pattern identical to the insulating spacer pattern.

Provided is a semiconductor device according to an example embodiment of the technical concept of the present disclosure. The semiconductor device includes: a first NMOS transistor structure; and a second NMOS transistor structure. The first NMOS transistor structure includes: a first NMOS source/drain region; first NMOS channel layers stacked and spaced apart from each other, and electrically connected to the first NMOS source/drain region in a first direction; a first NMOS gate electrode extending in a second direction crossing the first direction, and surrounding each of the first NMOS channel layers in the second horizontal direction; a first NMOS gate dielectric layer between the first NMOS gate electrode and the first NMOS channel layers, and between the first NMOS gate electrode and the first NMOS source/drain region; and a first NMOS insulating spacer structure between the first NMOS gate dielectric layer and the first NMOS source/drain region. The second NMOS transistor structure includes: a second NMOS source/drain region; second NMOS channel layers stacked and spaced apart from each other, and electrically connected to the second NMOS source/drain region in the first direction; a second NMOS gate electrode extending in the second direction, and surrounding each of the second NMOS channel layers in the second direction; a second NMOS gate dielectric layer between the second NMOS gate electrode and the second NMOS channel layers, and between the second NMOS gate electrode and the second NMOS source/drain region; and a second NMOS insulating spacer structure between the second NMOS gate dielectric layer and the second NMOS source/drain region. The first NMOS channel layers include a first NMOS lower channel layer, a first NMOS intermediate channel layer on the first NMOS lower channel layer, and a first NMOS upper channel layer on the first NMOS intermediate channel layer, and the second NMOS channel layers include a second NMOS lower channel layer, a second NMOS intermediate channel layer on the second NMOS lower channel layer, and a second NMOS upper channel layer on the second NMOS intermediate channel layer. The first NMOS gate electrode includes: a first NMOS lower gate portion directly below the first NMOS lower channel layer; a first NMOS intermediate gate portion directly below the first NMOS intermediate channel layer; and a first NMOS upper gate portion directly below the first NMOS upper channel layer. The second NMOS gate electrode includes: a second NMOS lower gate portion directly below the second NMOS lower channel layer; a second NMOS intermediate gate portion directly below the second NMOS intermediate channel layer; and a second NMOS upper gate portion directly below the second NMOS upper channel layer. The first NMOS insulating spacer structure includes a first NMOS intermediate spacer portion between the first NMOS source/drain region and the first NMOS intermediate gate portion, the second NMOS insulating spacer structure includes a second NMOS intermediate spacer portion between the second NMOS source/drain region and the second NMOS intermediate gate portion, a thickness of the first NMOS intermediate spacer portion is greater than a thickness of the second NMOS intermediate spacer portion, the thickness of the second NMOS intermediate spacer portion is a thickness perpendicular to a surface of the second NMOS gate dielectric layer in contact with the second NMOS intermediate spacer portion, of the second NMOS gate dielectric layer, and the thickness of the first NMOS intermediate spacer portion is a thickness perpendicular to a surface of the first NMOS gate dielectric layer in contact with or facing the first NMOS intermediate spacer portion, of the first NMOS gate dielectric layer.

Provided is a semiconductor device according to an example embodiment of the technical concept of the present disclosure. The semiconductor device includes a first NMOS transistor structure; and a second NMOS transistor structure. The first NMOS transistor structure includes: first NMOS channel layers spaced apart from each other in a first direction; a first NMOS source/drain region electrically connected to the first NMOS channel layers in a second direction, perpendicular to the first direction; a first NMOS gate electrode including a first NMOS intermediate electrode portion between the first NMOS channel layers; a first NMOS gate dielectric layer between the first NMOS gate electrode and the first NMOS channel layers; and a first NMOS insulating spacer structure between the first NMOS intermediate electrode portion and the first NMOS source/drain region. The second NMOS transistor structure includes: second NMOS channel layers spaced apart from each other in the first direction; a second NMOS source/drain region connected to the second NMOS channel layers in the second direction; a second NMOS gate electrode including a second NMOS intermediate electrode portion between the second NMOS channel layers; a second NMOS gate dielectric layer between the second NMOS gate electrode and the second NMOS channel layers; and a second NMOS insulating spacer structure between the second NMOS intermediate electrode portion and the second NMOS source/drain region. The first NMOS insulating spacer structure includes an insulating spacer pattern, and the second NMOS insulating spacer structure includes a second NMOS insulating oxide layer and does not include an insulating spacer pattern identical to the insulating spacer pattern.

According to example embodiments, first and second NMOS transistor structures including source/drain regions having different widths and different insulating spacer structures may be provided. Accordingly, a first NMOS transistor capable of preventing or minimizing leakage current caused by a Gate-Induced Drain Leakage (GIDL) phenomenon and a second NMOS transistor including source/drain regions that may be reliably formed may be provided.

Advantages and effects of the present disclosure are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIGS. 1A, 1B, 2, 3A, 3B, 4, 5, 6A, 6B, and 7 are views illustrating a semiconductor device according to example embodiments of the present disclosure;

FIG. 8 is a partially enlarged cross-sectional view illustrating an example of a semiconductor device according to example embodiments of the present disclosure;

FIG. 9 is a partially enlarged cross-sectional view illustrating an example of a semiconductor device according to example embodiments of the present disclosure;

FIG. 10 is a partially enlarged cross-sectional view illustrating an example of a semiconductor device according to example embodiments of the present disclosure;

FIGS. 11, 12, and 13 are views illustrating an example of a semiconductor device according to example embodiments of the present disclosure;

FIGS. 14 and 15 are cross-sectional views illustrating an example of a semiconductor device according to example embodiments of the present disclosure; and

FIGS. 16A, 16B, 17A, 17B, 18 to 23, 24A, 24B, 25A, 25B, 25C, 25D, 25D, 26A, and 26B are views illustrating an example of a forming method of a semiconductor device according to example embodiments of the present disclosure.

### DETAILED DESCRIPTION

Hereinafter, the terms such as “upper,” “intermediate,” and “lower” may be replaced with other terms such as “first,” “second,” and “third” and may be used to describe elements of the specification. The terms such as “first,” “second,” and “third” may be used to describe various elements, but the elements are not limited thereto, and the “first element” could be termed “second element.” In the specification, terms such as ‘lower portion,’ ‘upper portion,’ ‘upper end,’ and ‘lower end’ may be terms explained based on the drawings. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

In the specification, “NMOS transistor” may refer to an N-channel MOSFET (N-Channel Metal-Oxide Semiconductor Field-Effect Transistor), and “PMOS transistor” may refer to a P-channel MOSFET (P-Channel Metal-Oxide Semiconductor Field-Effect Transistor).

In the specification, to clearly distinguish between the elements of the NMOS transistor and the elements of the PMOS transistor, a gate, a channel layer, and a source/drain, which are elements of the “NMOS transistor,” are referred to as an NMOS gate, an NMOS channel layer, and an NMOS source/drain, respectively, and a gate, a channel layer, and a source/drain, which are elements of the “PMOS transistor,” are referred to as a PMOS gate, a PMOS channel layer, and a PMOS source/drain, respectively.

In the specification, “transistor structure” may mean a structure including a “transistor.”

In the specification, to distinguish between the elements of a “first NMOS transistor structure,” the elements of a “second NMOS transistor structure,” the elements of a “first PMOS transistor structure,” and the elements of a “first PMOS transistor structure,” the elements of the “first NMOS transistor structure” are referred to as first NMOS elements, the elements of the “second NMOS transistor structure” are referred to as second NMOS elements, the elements of the “first PMOS transistor structure” are referred to as first PMOS elements, and the elements of the “second PMOS transistor structure” are referred to as second PMOS elements.

The term “surrounding” as may be used herein may not require completely surrounding the described elements or layers, but may, for example, refer to partially surrounding the described elements or layers, for example, with voids or other spaces throughout. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

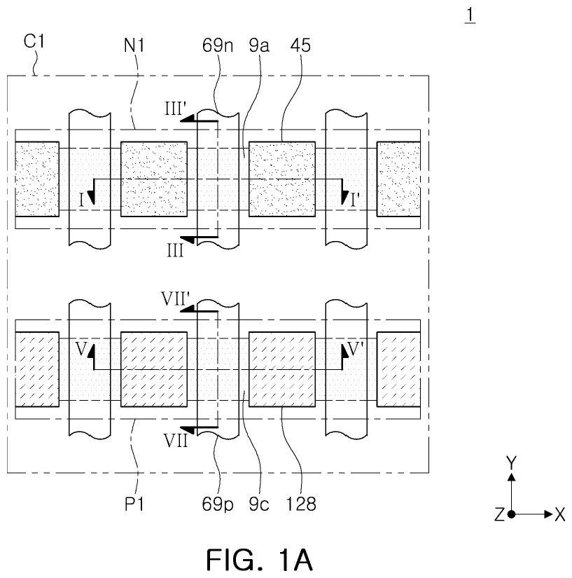

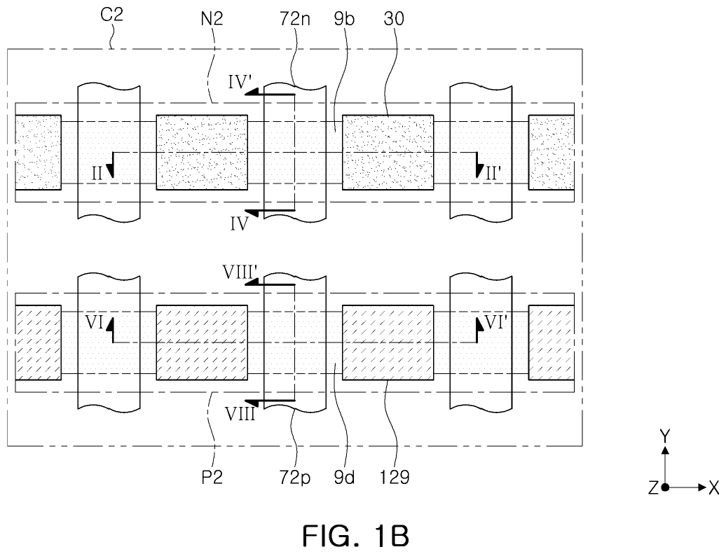

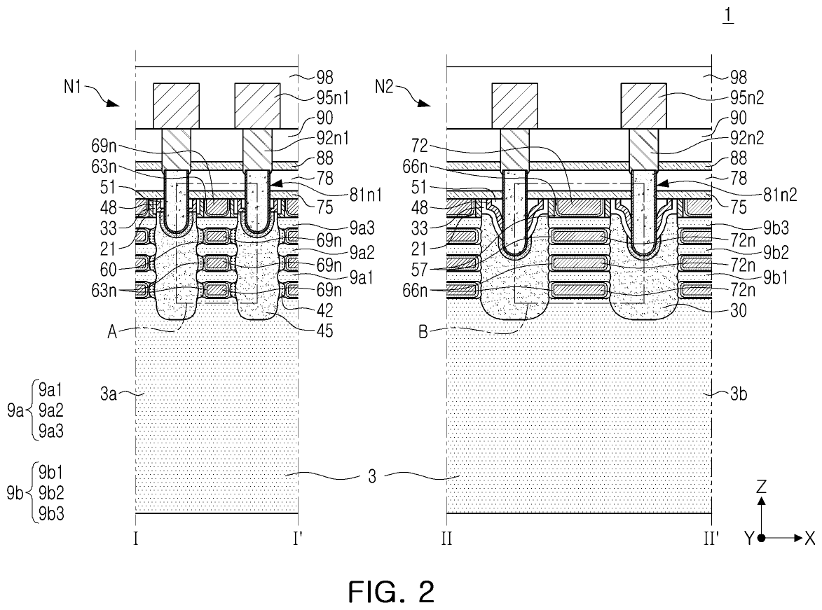

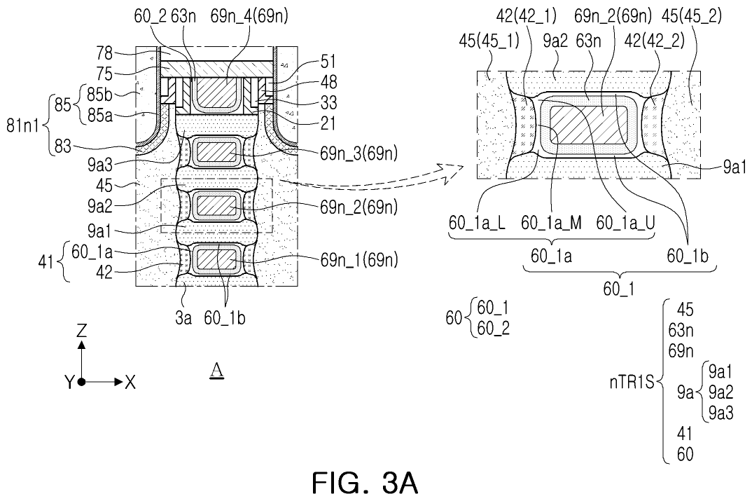

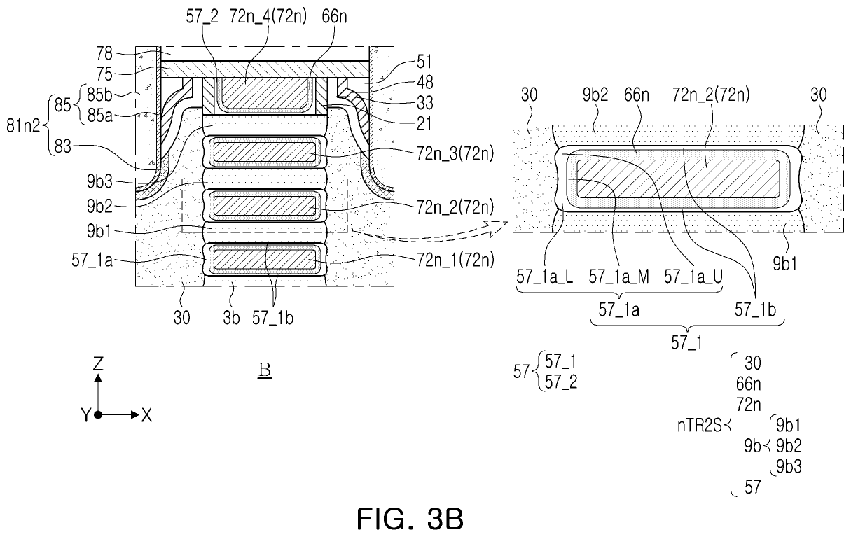

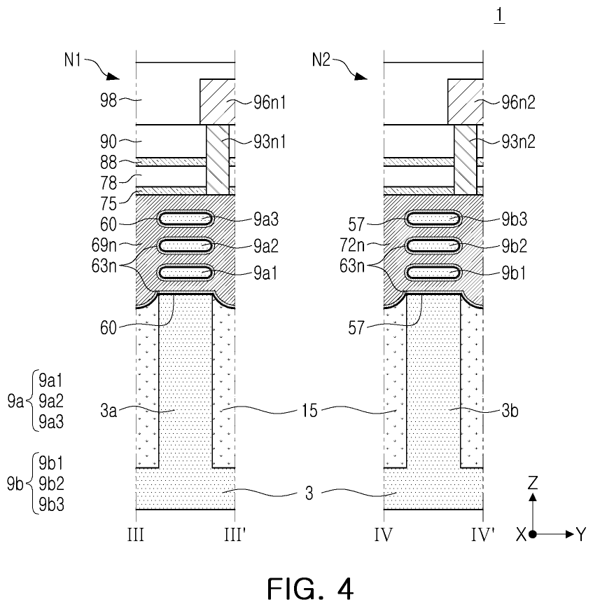

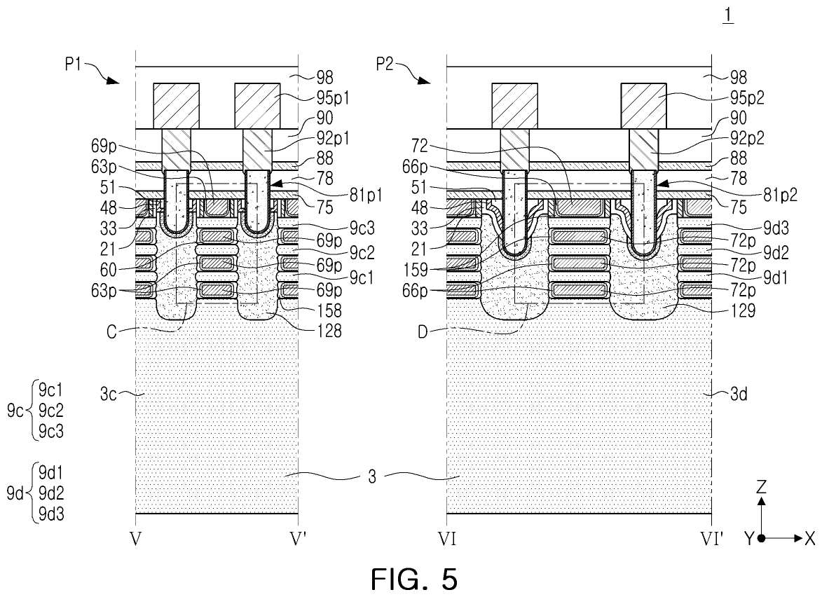

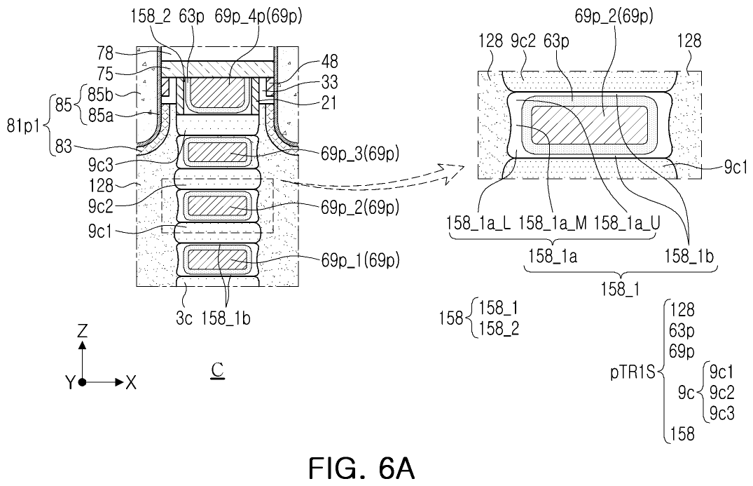

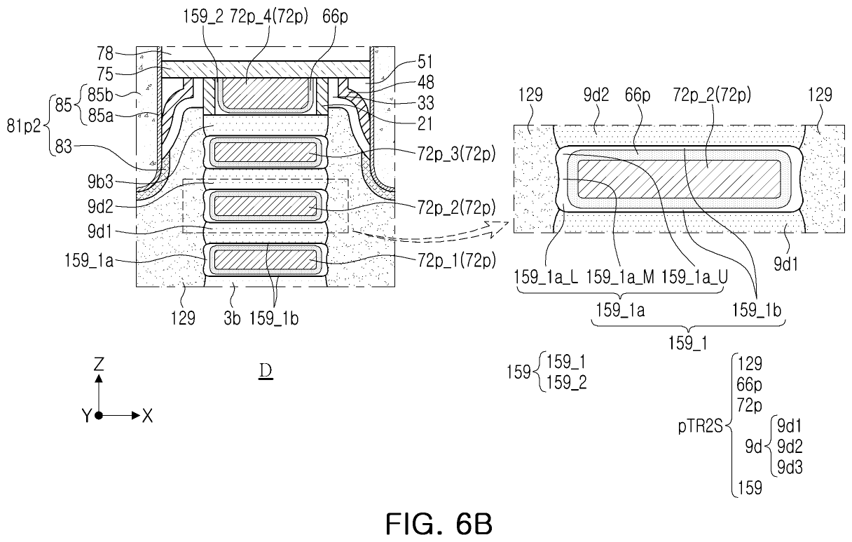

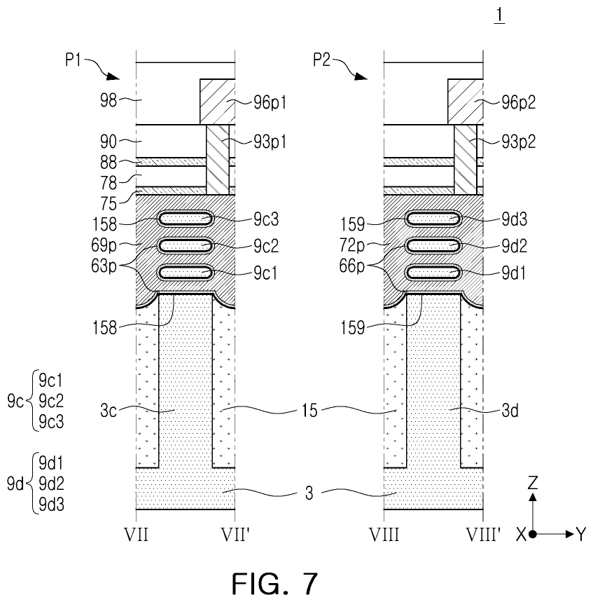

With reference to FIGS. 1A, 1B, 2, 3A, 3B, 4, 5, 6A, 6B and 7, a semiconductor device according to an example embodiment of the present disclosure will be described. In FIG. 1A, FIG. 1B, FIG. 2, FIG. 3A, FIG. 3B, FIG. 4, FIG. 5, FIG. 6A, FIG. 6B, and FIG. 7, FIG. 1A is a plan view illustrating a first region C1 of a semiconductor device according to an example embodiment of the present disclosure, FIG. 1B is a plan view illustrating a second region C2 of a semiconductor device according to an example embodiment of the present disclosure, FIG. 2 is a cross-sectional view illustrating regions taken along line I-I′ of FIG. 1A and line II-II′ of FIG. 1B, FIG. 3A is a partially enlarged view of a portion indicated by ‘A’ of FIG. 2, FIG. 3B is a partially enlarged view of a portion indicated by ‘B’ of FIG. 2, FIG. 4 is a cross-sectional view illustrating regions taken along line III-III′ of FIG. 1A and line IV-IV′ of FIG. 1B, FIG. 5 is a cross-sectional view illustrating regions taken along line V-V′ of FIG. 1A and line VI-VI′ of FIG. 1B, FIG. 6A is a partially enlarged view of a portion indicated by ‘C’ in FIG. 5, FIG. 6B is a partially enlarged view of a portion indicated by ‘D’ in FIG. 5, and FIG. 7 is a cross-sectional view illustrating regions taken along the line VII-VII′ in FIG. 1A and the line VIII-VIII′ in FIG. 1B.

Referring to FIGS. 1A, 1B, 2, 3A, 3B, 4, 5, 6A, 6B and 7, a semiconductor device 1 according to an example embodiment may include the first region C1 and the second region 2.

The first region C1 may include a first NMOS transistor region N1, and the second region C2 may include a second NMOS transistor region N2. The first region C1 may further include a first PMOS transistor region P1, and the second region C2 may further include a second PMOS transistor region P2.

The first NMOS transistor region N1 may include a first NMOS transistor structure nTR1S, and the second NMOS transistor region N2 may include a second NMOS transistor structure nTR2S. The first PMOS transistor region P1 may include a first PMOS transistor structure pTR1S, and the second PMOS transistor region P2 may include a second PMOS transistor structure pTR2S.

The first NMOS transistor region N1, the second NMOS transistor region N2, the first PMOS transistor region P1 and the second PMOS transistor region P2 may further include a substrate 3, active regions 3a, 3b, 3c and 3d on the substrate 3, and a device isolation region 15 disposed on side surfaces of the active regions 3a, 3b, 3c and 3d on the substrate 3.

The substrate 3 may be a semiconductor substrate, for example, a single crystal silicon substrate. Each of the active regions 3a, 3b, 3c and 3d may have a shape protruding vertically from the substrate 3. The active regions 3a, 3b, 3c and 3d may include a semiconductor material, for example, single crystal silicon. The device isolation region 15 may include an insulating material such as silicon oxide.

The first NMOS transistor region N1 may include a first active region 3a, among the active regions 3a, 3b, 3c and 3d, the second NMOS transistor region N2 may include a second active region 3b, among the active regions 3a, 3b, 3c and 3d, the first PMOS transistor region P1 may include a third active region 3c, among the active regions 3a, 3b, 3c and 3d, and the second PMOS transistor region P1 may include a fourth active region 3d, among the active regions 3a, 3b, 3c and 3d.

The first NMOS transistor structure nTRIS (see FIG. 3A) may include first NMOS source/drain regions 45, first NMOS channel layers 9a, a first NMOS gate electrode 69n, a first NMOS gate dielectric layer 63n, and a first NMOS insulating spacer structure 41.

The first NMOS source/drain regions 45 may be spaced apart from each other in a first horizontal direction (X-direction). Each of the first NMOS source/drain regions 45 may have an N-type conductivity. Each of the first NMOS source/drain regions 45 may include an epitaxially grown semiconductor material. For example, each of the first NMOS source/drain regions 45 may include silicon.

The first NMOS channel layers 9a may be disposed between the first NMOS source/drain regions 45. The first NMOS channel layers 9a may be disposed on the first active region 3a. The first NMOS channel layers 9a may be stacked while being spaced apart from each other in a vertical direction (Z-direction), perpendicular to the first horizontal direction (X-direction). The first NMOS channel layers 9a may be connected to the first NMOS source/drain regions 45. The first NMOS channel layers 9a may include a semiconductor material, for example, single crystal silicon.

The first NMOS channel layers 9a may include a first NMOS lower channel layer 9a1 on the first active region 3a, a first NMOS intermediate channel layer 9a2 on the first NMOS lower channel layer 9a1, and a first NMOS upper channel layer 9a3 on the first NMOS intermediate channel layer 9a2. In FIGS. 2 and 3A, the number of first NMOS channel layers 9a is illustrated as three, but the example embodiment is not limited thereto. For example, the first NMOS channel layers 9a may include four or more channel layers stacked while being spaced apart from each other in the vertical direction (Z-direction).

The first NMOS gate electrode 69n may extend in a second horizontal direction (Y-direction), perpendicular to the first horizontal direction (X-direction) and the vertical direction (Z-direction) and may surround each of the first NMOS channel layers 9a. The first NMOS gate electrode 69n may surround each of the first NMOS channel layers 9a and may extend in the second horizontal direction (Y-direction) and may be disposed on the first active region 3a and the device isolation region 15.

The first NMOS gate electrode 69n may include a first NMOS lower gate portion 69n_1 directly below the first NMOS lower channel layer 9a1, a first NMOS intermediate gate portion 69n_2 directly below the first NMOS intermediate channel layer 9a2, a first NMOS upper gate portion 69n_3 directly below the first NMOS upper channel layer 9a3, and a second NMOS upper gate portion 69n_4 on the first NMOS upper channel layer 9a3. The first NMOS lower gate portion 69n_1 may be disposed between the first active region 3a and the first NMOS lower channel layer 9a1, the first NMOS intermediate gate portion 69n_2 may be disposed between the first NMOS lower channel layer 9a1 and the first NMOS intermediate channel layer 9a2, and the first NMOS upper gate portion 69n_3 may be disposed between the first NMOS intermediate channel layer 9a2 and the first NMOS upper channel layer 9a3.

The first NMOS gate dielectric layer 63n may be disposed between the first NMOS source/drain regions 45 and the first NMOS gate electrode 69n and may extend between the first NMOS gate electrode 69n and the first NMOS channel layers 9a. The first NMOS gate dielectric layer 63n may include a high-dielectric. The high-K dielectric may be a dielectric having a dielectric constant higher than a dielectric constant of silicon oxide.

The first NMOS insulating spacer structure 41 may be disposed between the first NMOS gate dielectric layer 63n and the first NMOS source/drain regions 45. The first NMOS insulating spacer structure 41 may vertically overlap the first NMOS channel layers 9a.

The first NMOS insulating spacer structure 41 may include insulating spacer patterns 42. The insulating spacer patterns 42 may be disposed between the first NMOS source/drain regions 45. The insulating spacer patterns 42 may vertically overlap the first NMOS channel layers 9a. The insulating spacer patterns 42 may include an insulating nitride. For example, the insulating spacer patterns 42 may include silicon nitride. The first NMOS source/drain regions 45 may include a first-first NMOS source/drain region 45_1 and a first-second NMOS source/drain region 45_2 spaced apart from each other in the first horizontal direction (X-direction). The insulating spacer patterns 42 may include a first-first insulating spacer pattern 42_1 disposed between the first-first NMOS source/drain region 45_1 and the first NMOS gate dielectric layer 63n and a first-second insulating spacer pattern 42_2 disposed between the first-second NMOS source/drain region 45_2 and the first NMOS gate dielectric layer 63n, disposed between the first NMOS source/drain region 45. The first-first insulating spacer pattern 42_1 may be in contact with the first-first NMOS source/drain region 45_1, and the first-second insulating spacer pattern 42_2 may be in contact with the first-second NMOS source/drain region 45_2.

In at least one of the first NMOS channel layers 9a, a maximum thickness of a portion vertically overlapping the first NMOS gate electrode 69n in the vertical direction (Z-direction) may be smaller than a maximum thickness of a portion vertically overlapping the insulating spacer patterns 42 in the vertical direction (Z-direction). In the at least one of the first NMOS channel layers 9a, the maximum thickness of the portion vertically overlapping the first NMOS gate electrode 69n in the vertical direction (Z-direction) may be smaller than a maximum thickness of a portion not vertically overlapping the first NMOS gate electrode 69n in the vertical direction (Z-direction). For example, the first NMOS intermediate channel layer 9a2 may have a first maximum thickness in a portion vertically overlapping the first NMOS intermediate gate portion 69n_2, and may have a second maximum thickness, greater than the first maximum thickness, in a portion not vertically overlapping the first NMOS intermediate gate portion 69n_2. A structure of the first NMOS channel layers 9a in this form may increase thicknesses of the first NMOS lower gate portion 69n_1, the first NMOS intermediate gate portion 69n_2 and the first NMOS upper gate portion 69n_3, thereby improving electrical characteristics of the first NMOS gate electrode 69n. Accordingly, the performance of the semiconductor device 1 may be improved.

In the first NMOS channel layers 9a, a thickness may refer to a thickness in the vertical direction (Z-direction).

The first NMOS transistor structure nTRIS may further include a first NMOS insulating oxide layer 60. The first NMOS insulating oxide layer 60 may include silicon oxide. A minimum thickness of the insulating spacer pattern 42 may be greater than a minimum thickness of the first NMOS insulating oxide layer 60. Here, a thickness of the insulating spacer pattern 42 may be a thickness in the first horizontal direction (X-direction), and a thickness of the first NMOS insulating oxide layer 60 may be a thickness in a direction, perpendicular to a surface of the first NMOS gate dielectric layer 63n in contact with the first NMOS insulating oxide layer 60.

The first NMOS insulating oxide layer 60 may include a first NMOS lower insulating oxide layer 60_1 and a first NMOS upper insulating oxide layer 60_2.

The first NMOS upper insulating oxide layer 60_2 may be in contact with an external surface of the first NMOS gate dielectric layer 63n disposed on a side surface of the first NMOS uppermost gate portion 69n_4 and a lower surface of the first NMOS gate dielectric layer 63n disposed below a lower surface of the first NMOS uppermost gate portion 69n_4.

A portion of the first NMOS lower insulating oxide layer 60_1 disposed below each of the first NMOS channel layers 9a of the first NMOS lower insulating oxide layer 60_1 may include spacer portions 60_1a and interfacial portions 60_1b. The interfacial portions 60_1b may be interfacial oxide layers.

The spacer portions 60_1a may be disposed between the insulating spacer patterns 42 and the first NMOS gate dielectric layer 63n. The interfacial portions 60_1b may extend from the spacer portions 60_1a, may vertically overlap the first NMOS gate electrode 69n and may be in contact with the first NMOS gate dielectric layer 63n. For example, the spacer portions 60_1a may include a portion disposed between the first-first insulating spacer pattern 42_1 and the first NMOS gate dielectric layer 63n, and a portion disposed between the first-second insulating spacer pattern 42_2 and the first NMOS gate dielectric layer 63n, and the interfacial portions 60_1b may include a portion in contact with a lower surface of the first NMOS gate dielectric layer 63n disposed below lower surfaces of each of the first NMOS lower gate portion 69n_1, the first NMOS intermediate gate portion 69n_2 and the first NMOS upper gate portion 69n_3, and a portion in contact with an upper surface of the first NMOS gate dielectric layer 63n disposed on upper surfaces of each of the first NMOS lower gate portion 69n_1, the first NMOS intermediate gate portion 69n_2 and the first NMOS upper gate portion 69n_3. For example, as in FIG. 3A, when viewed as a center with respect to the first NMOS intermediate gate portion 69n_2, the spacer portions 60_1a may include a portion disposed between the first-first insulating spacer pattern 42_1 and the first NMOS gate dielectric layer 63n and a portion disposed between the first-second insulating spacer pattern 42_2 and the first gate dielectric layer 63n, the interfacial portions 60_1b may extend from the spacer portions 60_1a, and the interfacial portions 60_1b may include a portion disposed between the first NMOS lower channel layer 9a1 and the first NMOS gate dielectric layer 63n and a portion disposed between the first NMOS intermediate channel layer 9a2 and the first NMOS gate dielectric layer 63n.

As in FIG. 3A, when viewed as a center with respect to the first-first insulating spacer pattern 42_1 and one spacer portion 60_1a in contact with the first-first insulating spacer pattern 42_1, the spacer portion 60_1a may include an intermediate portion 60_1a_M disposed between the first-first insulating spacer pattern 42_1 and the first NMOS gate dielectric layer 63n, a lower portion 60_1a_L extending downwardly from the intermediate portion 60_1a_M and having a maximum thickness greater than a thickness of the intermediate portion 60_1a_M, and an upper portion 60_1a_U extending upwardly from the intermediate portion 60_1a_M and having a maximum thickness greater than a thickness of the first intermediate portion 60_1a_M.

In the first NMOS lower insulating oxide layer 60_1, thicknesses of each of the spacer portions 60_1a may be greater than the thickness of each of the interfacial portions 60_1b.

In the first NMOS lower insulating oxide layer 60_1, thicknesses of each portion of the first NMOS lower insulating oxide layer 60_1 may refer to a thickness in a direction, perpendicular to a surface of the first NMOS gate dielectric layer 63n in contact with the first NMOS lower insulating oxide layer 60_1.

The first NMOS insulating spacer structure 41 may include the insulating spacer patterns 42 and the spacer portions 60_1a of the first NMOS lower insulating oxide layer 60_1.

The first NMOS source/drain regions 45, the first NMOS channel layers 9a, the first NMOS gate electrode 69n and the first NMOS gate dielectric layer 63n may form a first NMOS transistor (45, 9a, and 69n or 63n of FIG. 3A), and the first NMOS insulating spacer structure 41 may improve the performance of a first NMOS transistor (45, 9a, and 69n or 63n of FIG. 3A). The first NMOS insulating spacer structure 41 may increase a separation distance between a drain region, among the first NMOS source/drain regions 45, and the first NMOS gate electrode 69n, thereby preventing or minimizing leakage current of the first NMOS transistor (45, 9a, and 69n or 63n of FIG. 3A) caused by a Gate-Induced Drain Leakage (GIDL) phenomenon.

The interfacial portions 60_1b of the first NMOS lower insulating oxide layer 60_1 may be disposed between the first NMOS channel layers 9a and the first NMOS gate dielectric layer 63n that may be formed of a high-K dielectric, thereby preventing interface defects that may occur when the first NMOS channel layers 9a and the first NMOS gate dielectric layer 63n are in contact with each other. Accordingly, the interfacial portions 60_1b of the first NMOS lower insulating oxide layer 60_1 may improve the performance and reliability of the first NMOS transistor (45, 9a, and 69n or 63n of FIG. 3A).

The second NMOS transistor structure nTR2S (see FIG. 3B) may include second NMOS source/drain regions 30, second NMOS channel layers 9b, second NMOS gate electrode 72n, and second NMOS gate dielectric layer 66n.

The second NMOS source/drain regions 30 may be spaced apart from each other in the first horizontal direction (X-direction). Each of the second NMOS source/drain regions 30 may have an N-type conductivity. The second NMOS source/drain regions 30 may be formed of the same material as the first NMOS source/drain regions 45.

In the first horizontal direction (X-direction), a width of each of the second NMOS source/drain regions 30 may be greater than a width of each of the first NMOS source/drain regions 45. A maximum width of the second NMOS source/drain region 30 in the first horizontal direction (X-direction) may be greater than a maximum width of the first NMOS source/drain region 45 in the first horizontal direction (X-direction).

The second NMOS channel layers 9b may be disposed between the second NMOS source/drain regions 30. The second NMOS channel layers 9b may be disposed on the second active region 3b. The second NMOS channel layers 9b may be stacked while being spaced apart from each other in the vertical direction (Z-direction). The second NMOS channel layers 9b may be connected to the second NMOS source/drain regions 30. The second NMOS channel layers 9b may include a semiconductor material, for example, single crystal silicon. The second NMOS channel layers 9b may be disposed at the same level as the first NMOS channel layers 9a.

The second NMOS channel layers 9b may include a second NMOS lower channel layer 9b1 on the second active region 3b, a second NMOS intermediate channel layer 9b2 on the second NMOS lower channel layer 9b1, and a second NMOS upper channel layer 9b3 on the second NMOS intermediate channel layer 9b2. Although the number of second NMOS channel layers 9b is illustrated as three in FIGS. 2 and 3B, but the example embodiment is not limited thereto. For example, the second NMOS channel layers 9b may include four or more channel layers stacked while being spaced apart from each other in the vertical direction (Z-direction).

A width of a second NMOS channel layer disposed at the first level in the first horizontal direction (X-direction), among the second NMOS channel layers 9b, may be greater than a width of a first NMOS channel layer disposed at the first level in the first horizontal direction (X-direction, among the first NMOS channel layers 9a. For example, in the first horizontal direction (X-direction), a width of the second NMOS intermediate channel layer 9b2 may be greater than a width of the first NMOS intermediate channel layer 9a2 disposed at the same level as the second NMOS intermediate channel layer 9b2. The second NMOS gate electrode 72n may extend in the second horizontal direction (Y-direction) and may surround each of the second NMOS channel layers 9b. The second NMOS gate electrode 72n may surround each of the second NMOS channel layers 9b and may extend in the second horizontal direction (Y-direction) and may be disposed on the second active region 3b and the device isolation region 15.

The second NMOS gate electrode 72n may include a second NMOS lower gate portion 72n_1 directly below the second NMOS lower channel layer 9b1, a second NMOS intermediate gate portion 72n_2 directly below the second NMOS intermediate channel layer 9b2, a second NMOS upper gate portion 72n_3 directly below the second NMOS upper channel layer 9b3, and a second NMOS uppermost gate portion 72n_4 on the second NMOS upper channel layer 9b3. The second NMOS lower gate portion 72n_1 may be disposed between the second active region 3b and the second NMOS lower channel layer 9b1, the second NMOS intermediate gate portion 72n_2 may be disposed between the second NMOS lower channel layer 9b1 and the second NMOS intermediate channel layer 9b2, and the second NMOS upper gate portion 72n_3 may be disposed between the second NMOS intermediate channel layer 9b2 and the second NMOS upper channel layer 9b3.

The second NMOS gate dielectric layer 66n may be disposed between the second NMOS source/drain regions 30 and the second NMOS gate electrode 72n and may extend between the second NMOS gate electrode 72n and the second NMOS channel layers 9b. The second NMOS gate dielectric layer 66n may include a high-κ dielectric.

In at least one of the second NMOS channel layers 9b, a maximum thickness of a portion vertically overlapping the second NMOS gate electrode 72n in the vertical direction (Z-direction) may be smaller than a maximum thickness of a portion not vertically overlapping the second NMOS gate electrode 72n in the vertical direction (Z-direction). In the second NMOS channel layers 9b, a thickness may refer to a thickness in the vertical direction (Z-direction).

The second NMOS transistor structure nTR2S may further include a second NMOS insulating oxide layer 57. The second NMOS insulating oxide layer 57 may include silicon oxide.

The second NMOS insulating oxide layer 57 may include a second NMOS lower insulating oxide layer 57_1 and a second NMOS upper insulating oxide layer 57_2.

The second NMOS upper insulating oxide layer 57_2 may be in contact with an external surface of the second NMOS gate dielectric layer 66n disposed on a side surface of the second NMOS uppermost gate portion 72n_4 and a lower surface of the second NMOS gate dielectric layer 66n disposed below a lower surface of the second NMOS uppermost gate portion 72n_4.

A portion of the second NMOS lower insulating oxide layer 57_1 disposed below each of the second NMOS channel layers 9b, among the second NMOS lower insulating oxide layer 57_1, may include spacer portions 57_1a and interfacial portions 57_1b. The interfacial portions 57_1b may be interfacial oxide layers.

The spacer portions 57_1a may be disposed between the second NMOS source/drain regions 30 and the second NMOS gate dielectric layer 66n. The spacer portions 57_1a may be in contact with the second NMOS source/drain regions 30 and the second NMOS gate dielectric layer 66n.

The spacer portions 57_1a may be defined as a second NMOS insulating spacer structure 57_1a.

The interfacial portions 57_1b may be in contact with the second NMOS gate dielectric layer 66n extending from the spacer portions 57_1a and vertically overlapping the second NMOS gate electrode 72n. The interfacial portions 57_1b may include a portion in contact with a lower surface of the second NMOS gate dielectric layer 66n disposed below a lower surface of each of the second NMOS lower gate portion 72n_1, the second NMOS intermediate gate portion 72n_2 and the second NMOS upper gate portion 72n_3, and a portion in contact with an upper surface of the second NMOS gate dielectric layer 66n disposed on an upper surface of each of the second NMOS lower gate portion 72n_1, the second NMOS intermediate gate portion 72n_2 and the second NMOS upper gate portion 72n_3. The interfacial portions 57_1b may extend from the spacer portions 57_1a.

As illustrated in FIG. 3B, when viewed as a center with respect to the second NMOS intermediate gate portion 72n_2, the interfacial portions 57_1b may include a portion disposed between the second NMOS lower channel layer 9b1 and the second NMOS gate dielectric layer 66n, and a portion disposed between the second NMOS intermediate channel layer 9b2 and the second NMOS gate dielectric layer 66n.

As in FIG. 3B, when viewed with respect to one spacer portion 57_1a, among the spacer portions 57_1a, the spacer portion 57_1a may include an intermediate portion 57_1a_M disposed in the middle, a lower portion 57_1a_L extending downwardly from the intermediate portion 57_1a_M and having a maximum thickness greater than a thickness of the intermediate portion 57_1a_M, and an upper portion 57_1a_U extending upwardly from the intermediate portion 57_1a_M and having a maximum thickness greater than a thickness of the first intermediate portion 57_1a_M.

In the second NMOS lower insulating oxide layer 57_1, thicknesses of each of the spacer portions 57_1a may be greater than thicknesses of each of the interfacial portions 57_1b.

In the second NMOS lower insulating oxide layer 57_1, a thickness of respective portions of the second NMOS lower insulating oxide layer 57_1 may refer to a thickness in a direction, perpendicular to a surface of the second NMOS gate dielectric layer 66n in contact with the second NMOS lower insulating oxide layer 57_1.

The second NMOS source/drain regions 30, the second NMOS channel layers 9b, the second NMOS gate electrode 72n and the second NMOS gate dielectric layer 66n may form a second NMOS transistor (30, 9b, and 72n or 66n of FIG. 3B), and the spacer portions 57_1a, i.e., the second NMOS insulating spacer structure 57_1a, may improve the performance of the second NMOS transistor (30, 9b, and 72n or 66n of FIG. 3B). The second NMOS insulating spacer structure 57_1a may increase the separation distance between a drain region of the second NMOS source/drain regions 30 and the second NMOS gate electrode 72n, thereby preventing or minimizing leakage current of the second NMOS transistor (30, 9b, and 72n or 66n of FIG. 3B) caused by the Gate-Induced Drain Leakage (GIDL) phenomenon.

Since the second NMOS transistor structure nTR2S does not include the insulating spacer patterns 42 of the first NMOS insulating spacer structure 41, it may be possible to reliably form the second NMOS source/drain regions 30 having a greater width than the first NMOS source/drain regions 45. Accordingly, the reliability of the second NMOS source/drain regions 30 having a width greater than that of the first NMOS source/drain regions 45 may be increased.

The interfacial portions 57_1b of the second NMOS lower insulating oxide layer 57_1 may be disposed between the second NMOS channel layers 9b and the second NMOS gate dielectric layer 66n that may be formed of a high-k dielectric, thus preventing interface defects that may occur when the second NMOS channel layers 9b and the second NMOS gate dielectric layer 66n are in contact with each other. Accordingly, the interfacial portions 57_1b of the second NMOS lower insulating oxide layer 57_1 may improve the performance and reliability of the second NMOS transistor (30, 9b, and 72n or 66n of FIG. 3B).

The first PMOS transistor structure pTRIS (see FIG. 6A) may include first PMOS source/drain regions 128, first PMOS channel layers 9c, a first PMOS gate electrode 69p, and a first PMOS gate dielectric layer 63p.

The first PMOS source/drain regions 128 may be spaced apart from each other in the first horizontal direction (X-direction). Each of the first PMOS source/drain regions 128 may have a P-type conductivity. Each of the first PMOS source/drain regions 128 may include an epitaxially grown semiconductor material. For example, each of the first PMOS source/drain regions 128 may include at least one of germanium (Ge) and silicon-germanium (SiGe).

The first PMOS channel layers 9c may be disposed between the first PMOS source/drain regions 128. The first PMOS channel layers 9c may be disposed on the third active region 3c. The first PMOS channel layers 9c may be stacked while being spaced apart from each other in the first vertical direction (Z-direction). The first PMOS channel layers 9c may be connected to the first PMOS source/drain regions 128. The first PMOS channel layers 9c may include a semiconductor material, for example, single crystal silicon.

The first PMOS channel layers 9c may include a first PMOS lower channel layer 9c1 on the third active region 3c, a first PMOS intermediate channel layer 9c2 on the first PMOS lower channel layer 9c1, and a first PMOS upper channel layer 9c3 on the first PMOS intermediate channel layer 9c2. In FIGS. 5 and 6A, the number of first PMOS channel layers 9c is illustrated as three, but the example embodiment is not limited thereto. For example, the first PMOS channel layers 9c may include four or more channel layers stacked while being spaced apart from each other in the vertical direction (Z-direction).

The first PMOS gate electrode 69p may extend in the second horizontal direction (Y-direction) and may surround each of the first PMOS channel layers 9c. The first PMOS gate electrode 69p may surround each of the first PMOS channel layers 9c and may extend in the second horizontal direction (Y-direction) and may be disposed on the third active region 3c and the device isolation region 15.

The first PMOS gate electrode 69p may include a first PMOS lower gate portion 69p_1 directly below the first PMOS lower channel layer 9c1, a first PMOS intermediate gate portion 69p_2 directly below the first PMOS intermediate channel layer 9c2, a first PMOS upper gate portion 69p_3 directly below the first PMOS upper channel layer 9c3, and a first PMOS uppermost gate portion 69p_4 on the first PMOS upper channel layer 9c3. The first PMOS lower gate portion 69p_1 may be disposed between the third active region 3c and the first PMOS lower channel layer 9c1, the first PMOS intermediate gate portion 69p_2 may be disposed between the first PMOS lower channel layer 9c1 and the first PMOS intermediate channel layer 9c2, and the first PMOS upper gate portion 69p_3 may be disposed between the first PMOS intermediate channel layer 9c2 and the first PMOS upper channel layer 9c3.

The first PMOS gate dielectric layer 63p may be disposed between the first PMOS source/drain regions 128 and the first PMOS gate electrode 69p and may extend between the first PMOS gate electrode 69p and the first PMOS channel layers 9c. The first PMOS gate dielectric layer 63p may include a high-κ dielectric.

In at least one of the first PMOS channel layers 9c, a maximum thickness of a portion vertically overlapping the first PMOS gate electrode 69p in the vertical direction (Z-direction) may be smaller than a maximum thickness of a portion not vertically overlapping the first PMOS gate electrode 69p in the vertical direction (Z-direction). In the first PMOS channel layers 9c, a thickness may refer to a thickness in the vertical direction (Z-direction).

The first PMOS transistor structure pTR1S may further include a first PMOS insulating oxide layer 158. The first PMOS insulating oxide layer 158 may include silicon oxide.

The first PMOS insulating oxide layer 158 may include a first PMOS lower insulating oxide layer 158_1 and a first PMOS upper insulating oxide layer 158_2.

The first PMOS upper insulating oxide layer 158_2 may be in contact with an external surface of the first PMOS gate dielectric layer 63p disposed on a side surface of the first PMOS uppermost gate portion 69p_4 and a lower surface of the first PMOS gate dielectric layer 63p disposed below a lower surface of the first PMOS uppermost gate portion 69p_4.

A portion of the first PMOS lower insulating oxide layer 158_1 disposed below each of the first PMOS channel layers 9c, among the first PMOS lower insulating oxide layers 158_1, may include spacer portions 158_1a and interfacial portions 158_1b.

The spacer portions 158_1a may be disposed between the first PMOS source/drain regions 128 and the first PMOS gate dielectric layer 63p. The spacer portions 158_1a may be in contact with the first PMOS source/drain regions 128 and the first PMOS gate dielectric layer 63p.

The spacer portions 158_1a may be defined as a first PMOS insulating spacer structure 158_1a.

The interfacial portions 158_1b may extend from the spacer portions 158_1a and may be in contact with the first PMOS gate dielectric layer 63p vertically overlapping the first PMOS gate electrode 69p. The interfacial portions 158_1b may include a portion in contact with a lower surface of the first PMOS gate dielectric layer 63p disposed below lower surfaces of each of the first PMOS lower gate portion 69p_1, the first PMOS intermediate gate portion 69p_2 and the first PMOS upper gate portion 69p_3, and a portion in contact with an upper surface of the first PMOS gate dielectric layer 63p disposed on upper surfaces of each of the first PMOS lower gate portion 69p_1, the first PMOS intermediate gate portion 69p_2 and the first PMOS upper gate portion 69p_3. The interfacial portions 158_1b may extend from the spacer portions 158_1a.

As illustrated in FIG. 6A, when viewed as a center with the first PMOS intermediate gate portion 69p_2, the interfacial portions 158_1b may include a portion disposed between the first PMOS lower channel layer 9c1 and the first PMOS gate dielectric layer 63p, and a portion disposed between the first PMOS intermediate channel layer 9c2 and the first PMOS gate dielectric layer 63p.

As illustrated in FIG. 6A, when viewed as a center at one of the spacer portions 158_1a from among the spacer portions 158_1a, the spacer portion 158_1a may include an intermediate portion 158_1a_M disposed in the middle, a lower portion 158_1a_L extending downwardly from the intermediate portion 158_1a_M and having a maximum thickness greater than a thickness of the intermediate portion 158_1a_M, and an upper portion 158_1a_U extending upwardly from the intermediate portion 158_1a_M and having a maximum thickness greater than a thickness of the first intermediate portion 158_1a_M.

In the first PMOS lower insulating oxide layer 158_1, thicknesses of each of the spacer portions 158_1a may be greater than thicknesses of each of the interfacial portions 158_1b.

In the first PMOS lower insulating oxide layer 158_1, thicknesses of each portion of the first PMOS lower insulating oxide layer 158_1 may refer to thicknesses in a direction, perpendicular to a surface of the first PMOS gate dielectric layer 63p in contact with the first PMOS lower insulating oxide layer 158_1.

The first PMOS source/drain regions 128, the first PMOS channel layers 9c, the first PMOS gate electrode 69p, and the first PMOS gate dielectric layer 63p may form a first PMOS transistor (128, 9c, and 69p or 63p of FIG. 6A), and the spacer portions 158_1a, i.e., the first PMOS insulating spacer structure 158_1a, may improve the performance of the first PMOS transistor (128, 9c, and 69p or 63p of FIG. 6A). The first PMOS insulating spacer structure 158_1a may increase a separation distance between a drain region of the first PMOS source/drain regions 128 and the first PMOS gate electrode 69p, thereby preventing or minimizing leakage current of the first PMOS transistor (128, 9c, and 69p or 63p of FIG. 6A) caused by the Gate-Induced Drain Leakage (GIDL) phenomenon.

The interfacial portions 158_1b of the first PMOS lower insulating oxide layer 158_1 may be disposed between the first PMOS channel layers 9c and the first PMOS gate dielectric layer 63p that may be formed of a high-κ dielectric, thereby preventing interface defects that may occur when the first PMOS channel layers 9c and the first PMOS gate dielectric layer 63p are in contact with each other. Accordingly, the interfacial portions 158_1b of the first PMOS lower insulating oxide layer 158_1 may improve the performance and reliability of the first PMOS transistor (128, 9c, and 69p or 63p of FIG. 6A).

The second PMOS transistor structure pTR2S (see FIG. 6B) may include second PMOS source/drain regions 129, second PMOS channel layers 9d, a second PMOS gate electrode 72p, and a second PMOS gate dielectric layer 66p.

The second PMOS source/drain regions 129 may be spaced apart from each other in the first horizontal direction (X-direction). Each of the second PMOS source/drain regions 129 may have a P-type conductivity. Each of the second PMOS source/drain regions 129 may include an epitaxially grown semiconductor material. For example, each of the second PMOS source/drain regions 129 may include at least one of germanium (Ge) or silicon-germanium (SiGe).

In the first horizontal direction (X-direction), a width of each of the second PMOS source/drain regions 129 may be greater than a width of each of the first PMOS source/drain regions 128.

The second PMOS channel layers 9d may be disposed between the second PMOS source/drain regions 129. The second PMOS channel layers 9d may be disposed on the fourth active region 3d. The second PMOS channel layers 9d may be stacked while being spaced apart from each other in the first vertical direction (Z-direction). The second PMOS channel layers 9d may be connected to the second PMOS source/drain regions 129. The second PMOS channel layers 9d may include a semiconductor material, for example, single crystal silicon.

The second PMOS channel layers 9d may include a second PMOS lower channel layer 9d1 on the fourth active region 3d, a second PMOS intermediate channel layer 9d2 on the second PMOS lower channel layer 9d1, and a second PMOS upper channel layer 9d3 on the second PMOS intermediate channel layer 9d2. Although the number of second PMOS channel layers 9d is illustrated as three in FIGS. 5 and 6B, the example embodiment is not limited thereto. For example, the second PMOS channel layers 9d may include four or more channel layers stacked while being spaced apart from each other in the vertical direction (Z-direction).

The second PMOS gate electrode 72p may extend in the second horizontal direction (Y-direction) and may surround the second PMOS channel layers 9d, respectively. The second PMOS gate electrode 72p may surround the second PMOS channel layers 9d, respectively, and may extend in the second horizontal direction (Y-direction) and may be disposed on the fourth active region 3d and the device isolation region 15.

The second PMOS gate electrode 72p may include a second PMOS lower gate portion 72p_1 directly below the second PMOS lower channel layer 9d1, a second PMOS intermediate gate portion 72p_2 directly below the second PMOS intermediate channel layer 9d2, a second PMOS upper gate portion 72p_3 directly below the second PMOS upper channel layer 9d3, and a second PMOS uppermost gate portion 72p_4 on the second PMOS upper channel layer 9d3. The second PMOS lower gate portion 72p_1 may be disposed between the fourth active region 3d and the second PMOS lower channel layer 9d1, the second PMOS intermediate gate portion 72p_2 may be disposed between the second PMOS lower channel layer 9dl and the second PMOS intermediate channel layer 9d2, and the second PMOS upper gate portion 72p_3 may be disposed between the second PMOS intermediate channel layer 9d2 and the second PMOS upper channel layer 9d3.

The second PMOS gate dielectric layer 66p may be disposed between the second PMOS source/drain regions 129 and the second PMOS gate electrode 72p and may extend between the second PMOS gate electrode 72p and the second PMOS channel layers 9d. The second PMOS gate dielectric layer 66p may include a high-κ dielectric.

In at least one of the second PMOS channel layers 9d, a maximum thickness of a portion vertically overlapping the second PMOS gate electrode 72p in the vertical direction (Z-direction) may be smaller than a maximum thickness of a portion not vertically overlapping the second PMOS gate electrode 72p in the vertical direction (Z-direction). In the second PMOS channel layers 9d, a thickness may refer to a thickness in the vertical direction (Z-direction).

The second PMOS transistor structure pTR2S may further include a second PMOS insulating oxide layer 159. The second PMOS insulating oxide layer 159 may include silicon oxide.

The second PMOS insulating oxide layer 159 may include a second PMOS lower insulating oxide layer 159_1 and a second PMOS upper insulating oxide layer 159_2.

The second PMOS upper insulating oxide layer 159_2 may be in contact with an external surface of the second PMOS gate dielectric layer 66p disposed on a side surface of the second PMOS upper gate portion 72p_4 and a lower surface of the second PMOS gate dielectric layer 66p disposed below a lower surface of the second PMOS upper gate portion 72p_4.

A portion of the second PMOS lower insulating oxide layer 159_1 disposed below each of the second PMOS channel layers 9d, among the second PMOS lower insulating oxide layers 159_1, may include spacer portions 159_1a and interfacial portions 159_1b.

The spacer portions 159_1a may be disposed between the second PMOS source/drain regions 129 and the second PMOS gate dielectric layer 66p. The spacer portions 159_1a may be in contact with the second PMOS source/drain regions 129 and the second PMOS gate dielectric layer 66p.

The spacer portions 159_1a may be defined as a second PMOS insulating spacer structure 159_1a.

The interfacial portions 159_1b may extend from the spacer portions 159_1a and may be in contact with the second PMOS gate dielectric layer 66p vertically overlapping the second PMOS gate electrode 72p. The interfacial portions 159_1b may include a portion in contact with a lower surface of the second PMOS gate dielectric layer 66p disposed below lower surfaces of each of the second PMOS lower gate portion 72p_1, the second PMOS intermediate gate portion 72p_2 and the second PMOS upper gate portion 72p_3, and a portion in contact with an upper surface of the second PMOS gate dielectric layer 66p disposed on upper surfaces of each of the second PMOS lower gate portion 72p_1, the second PMOS intermediate gate portion 72p_2 and the second PMOS upper gate portion 72p_3. The interfacial portions 159_1b may extend from the spacer portions 159_1a.

As illustrated in FIG. 6B, when viewed as a center with respect to the second PMOS intermediate gate portion 72p_2, the interfacial portions 159_1b may include a portion disposed between the second PMOS lower channel layer 9dl and the second PMOS gate dielectric layer 66p and a portion disposed between the second PMOS intermediate channel layer 9d2 and the second PMOS gate dielectric layer 66p.

As in FIG. 6B, when viewed as a center with respect to one spacer portion 159_1, among the spacer portions 159_1a, the spacer portion 159_1a may include an intermediate portion 159_1a_M disposed in the middle, a lower portion 159_1a_L extending downwardly from the intermediate portion 159_1a_M and having a maximum thickness greater than a thickness of the intermediate portion 159_1a_M, and an upper portion 159_1a_U extending upwardly from the intermediate portion 159_1a_M and having a maximum thickness greater than a thickness of the first intermediate portion 159_1a_M.

In the second PMOS lower insulating oxide layer 159_1, thicknesses of each of the spacer portions 159_1a may be greater than thicknesses of each of the interfacial portions 159_1b.

In the second PMOS lower insulating oxide layer 159_1, thicknesses of each portion of the second PMOS lower insulating oxide layer 159_1 may refer to thicknesses in a direction, perpendicular to a surface of the second PMOS gate dielectric layer 66p in contact with the second PMOS lower insulating oxide layer 159_1.

The second PMOS source/drain regions 129, the second PMOS channel layers 9d, the second PMOS gate electrode 72p and the second PMOS gate dielectric layer 66p may form a second PMOS transistor (129, 9d, and 72p or 66p of FIG. 6B), and the spacer portions 159_1a, i.e., the second PMOS insulating spacer structure 159_1a, may improve the performance of the second PMOS transistor (129, 9d, and 72p or 66p of FIG. 6B). The second PMOS insulating spacer structure 159_1a may increase a separation distance between a drain region of the second PMOS source/drain regions 129 and the second PMOS gate electrode 72p, thereby preventing or minimizing leakage current of the second PMOS transistor (129, 9d, and 72p or 66p of FIG. 6B) caused by the Gate-Induced Drain Leakage (GIDL) phenomenon.

The interfacial portions 159_1b of the second PMOS lower insulating oxide layer 159_1 may be disposed between the second PMOS channel layers 9d and the second PMOS gate dielectric layer 66p that may be formed of a high-κ dielectric, thereby preventing interface defects that may occur when the second PMOS channel layers 9d and the second PMOS gate dielectric layer 66p are in contact with each other. Accordingly, the interfacial portions 159_1b of the second PMOS lower insulating oxide layer 159_1 may improve the performance and reliability of the second PMOS transistor (129, 9d, and 72p or 66p of FIG. 6B).

The semiconductor device 1 may further include a first insulating liner 21, a second insulating liner 33, a third insulating liner 48, and an interlayer insulating layer 51.

Within the first NMOS region N1, the interlayer insulating layer 51 may be disposed on the first NMOS source/drain regions 45, the third insulating liner 48 may cover a side surface and a lower surface of the interlayer insulating layer 51, the second insulating liner 33 may be disposed between the third insulating liner 48 and the first NMOS upper insulating oxide layer 60_2, and the first insulating liner 21 may be disposed between the second insulating liner 33 and the first NMOS upper insulating oxide layer 60_2 and may be disposed between the second insulating liner 33 and the first NMOS upper channel layer 9a3. Within the first NMOS region N1, the first and second insulating liners 21 and 33 may be disposed on the first NMOS upper channel layer 9a3, and the third insulating liner 48 may be disposed on the first NMOS source/drain regions 45.

Within the second NMOS region N2, the interlayer insulating layer 51 may be disposed on the second NMOS source/drain regions 30, the third insulating liner 48 may cover a side surface and a lower surface of the interlayer insulating layer 51, the second insulating liner 33 may be disposed between the third insulating liner 48 and the second NMOS upper insulating oxide layer 57_2 and between the second NMOS source/drain regions 30 and the third insulating liner 48, and the first insulating liner 21 may be disposed between the second insulating liner 33 and the second NMOS upper insulating oxide layer 57_2.

Within the first PMOS region P1, the interlayer insulating layer 51 may be disposed on the first PMOS source/drain regions 128, the third insulating liner 48 may cover a side surface and a lower surface of the interlayer insulating layer 51, the second insulating liner 33 may be disposed between the third insulating liner 48 and the first PMOS upper insulating oxide layer 158_2 and between the first PMOS source/drain regions 128 and the third insulating liner 48, and the first insulating liner 21 may be disposed between the second insulating liner 33 and the first PMOS upper insulating oxide layer 158_2.

Within the second PMOS region P2, the interlayer insulating layer 51 may be disposed on the second PMOS source/drain regions 129, the third insulating liner 48 may cover a side surface and a lower surface of the interlayer insulating layer 51, the second insulating liner 33 may be disposed between the third insulating liner 48 and the second PMOS upper insulating oxide layer 159_2 and between the second PMOS source/drain regions 129 and the third insulating liner 48, and the first insulating liner 21 may be disposed between the second insulating liner 33 and the second PMOS upper insulating oxide layer 159_2.

The upper surfaces of the first NMOS gate electrode 69n, the second NMOS gate electrode 72n, the first PMOS gate electrode 69p, the second PMOS gate electrode 72p, the first NMOS gate dielectric layer 63n, the second NMOS gate dielectric layer 66n, the first PMOS gate dielectric layer 63p, the second NMOS gate dielectric layer 66n, the first NMOS insulating oxide layer 60, the second NMOS insulating oxide layer 57, the first PMOS insulating oxide layer 158, the second PMOS insulating oxide layer 159, the first insulating liner 21, the second insulating liner 33, the third insulating liner 48, and the interlayer insulating layer 51 may be coplanar with each other.

The semiconductor element 1 may further include a first capping insulating layer 75, a first intermetal insulating layer 78, a second capping insulating layer 88, a second intermetal insulating layer 90, and a third intermetal insulating layer 98, which are sequentially stacked.

Thicknesses of each of the first to third intermetal insulating layers 78, 90 and 98 may be greater than thicknesses of each of the first and second capping insulating layers 75 and 88.

The first capping insulating layer 75 may cover or be on the first NMOS gate electrode 69n, the second NMOS gate electrode 72n, the first PMOS gate electrode 69p, the second PMOS gate electrode 72p, the first NMOS gate dielectric layer 63n, the second NMOS gate dielectric layer 66n, the first PMOS gate dielectric layer 63p, the second NMOS gate dielectric layer 66n, the first NMOS insulating oxide layer 60, the second NMOS insulating oxide layer 57, the first PMOS insulating oxide layer 158, the second PMOS insulating oxide layer 159, the first insulating liner 21, the second insulating liner 33, the third insulating liner 48, and the interlayer insulating layer 51.

The first and second capping insulating layers 75 and 88 may include a different material from the first to third intermetal insulating layers 78, 90 and 98 and the interlayer insulating layer 51. For example, the first and second capping insulating layers 75 and 88 may include silicon nitride or metal oxide, and the first to third intermetal insulating layers 78, 90 and 98 and the interlayer insulating layer 51 may include silicon oxide or a low-κ dielectric having a dielectric constant lower than that of silicon oxide.

The semiconductor device 1 may further include source/drain contact structures 81n1, 81n2, 81p1 and 81p2.

Each of the source/drain contact structures 81n1, 81n2, 81p1 and 81p2 may be in contact with and electrically connected to a corresponding source/drain region, among the source/drain regions 45, 30, 128 and 129. For example, each of the source/drain contact structures 81n1, 81n2, 81p1 and 81p2 may include a metal-semiconductor compound layer 83 and a source/drain contact plug 85 on the metal-semiconductor compound layer 83. The source/drain contact plug 85 may include a plug conductive pattern 85b and a conductive barrier layer 85a covering a side surface and a lower surface of the plug conductive pattern 85b. In each of the source/drain contact structures 81n1, 81n2, 81p1 and 81p2, the metal-semiconductor compound layer 83 may be in contact with a corresponding source/drain region, among the source/drain regions 45, 30, 128 and 129. In each of the source/drain contact structures 81n1, 81n2, 81p1 and 81p2, the metal-semiconductor compound layer 83 may be disposed between a corresponding source/drain region, among the source/drain regions 45, 30, 128 and 129, and the source/drain contact plug 85.

The second capping insulating layer 88 may be disposed on upper surfaces of the source/drain contact structures 81n1, 81n2, 81p1 and 81p2 and an upper surface of the first intermetal insulating layer 78.

The semiconductor device 1 may further include gate contact structures 93n1, 93n2, 93p1 and 93p2.

The gate contact structures 93n1, 93n2, 93p1 and 93p2 may penetrate through the second intermetal insulating layer 90, the second capping insulating layer 88, the first intermetal insulating layer 78, and the first capping insulating layer 75 and may be electrically connected to the gate electrodes 69n, 72n, 69p and 72p. Each of the gate contact structures 93n1, 93n2, 93p1 and 93p2 may be electrically connected to a corresponding gate electrode among the gate electrodes 69n, 72n, 69p and 72p. The gate contact structures 93n1, 93n2, 93p1 and 93p2 may include a first NMOS gate contact structure 93n1 connected to the first NMOS gate electrode 69n, a second NMOS gate contact structure 93n2 connected to the second NMOS gate electrode 72n, a first PMOS gate contact structure 93p1 connected to the first PMOS gate electrode 69p, and a second PMOS gate contact structure 93p2 connected to the second PMOS gate electrode 72p.

The semiconductor device 1 may further include interconnection structures 95n1, 95n2, 95p1, 95p2, 96n1, 96n2, 96p1 and 96p2 electrically connected to the gate contact structures 93n1, 93n2, 93p1 and 93p2 and the source/drain contact structures 81n1, 81n2, 81p1 and 81p2. The interconnection structures 95n1, 95n2, 95p1, 95p2, 96n1, 96n2, 96p1 and 96p2 may be disposed on the second intermetallic insulating layer 90, the gate contact structures 93n1, 93n2, 93p1 and 93p2 and the source/drain contact structures 81n1, 81n2, 81p1 and 81p2. Each of the interconnection structures 95n1, 95n2, 95p1, 95p2, 96n1, 96n2, 96p1 and 96p2 may be connected to a corresponding contact structure, among the gate contact structures 93n1, 93n2, 93p1 and 93p2 and the source/drain contact structures 81n1, 81n2, 81p1 and 81p2. The second intermetallic insulating layer 98 may be disposed on the second intermetallic insulating layer 90 and the interconnection structures 95n1, 95n2, 95p1, 95p2, 96n1, 96n2, 96p1 and 96p2.

Next, various modified example embodiments of the elements of the above-described embodiment will be described. The various modified example embodiments of the elements of the above-described embodiments described below will be described with a focus on the modified or replaced elements. Here, the previously described elements may be directly cited without a separate detailed description, or descriptions thereof may be omitted. In addition, the modified or replaced elements described below are described with reference to the drawings below, but the modified or replaced elements may be combined with each other or with the previously described elements to form the semiconductor device 1 according to an example embodiment of the present disclosure.

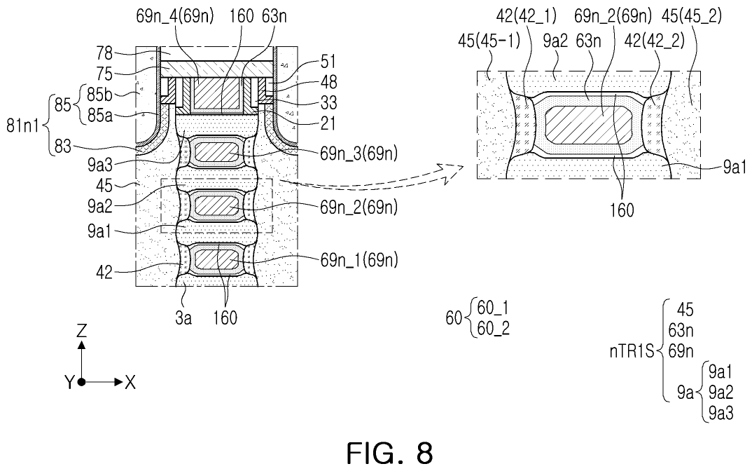

FIG. 8 is a partially enlarged cross-sectional view illustrating a modified portion in the partially enlarged view of FIG. 3A to explain an exemplary example of a semiconductor device according to an example embodiment of the present disclosure.

In an example embodiment, referring to FIG. 8, the first NMOS insulating oxide layer 60 (see FIG. 3A) described above may be replaced with a first NMOS insulating oxide layer 160 formed in a form in which the spacer portions 60_1a (see FIG. 3A) are omitted and the interfacial portions 60_1b (see FIG. 3A) remain. That is, the first NMOS insulating oxide layer 160 may replace the interfacial portions 60_1b of FIG. 3A. The first NMOS insulating oxide layer 160 may be disposed between the first NMOS gate dielectric layer 63n and the first NMOS channel layers 9a, and between the first NMOS gate dielectric layer 63n and the first active region 3a.

As the first NMOS insulating oxide layer 60 (see FIG. 3A) described above is replaced with the first NMOS insulating oxide layer 160, the first NMOS insulating spacer structure 41 (see FIG. 3A) described above may be replaced with the insulating spacer patterns 42 in contact with the first NMOS gate dielectric layer 63n.

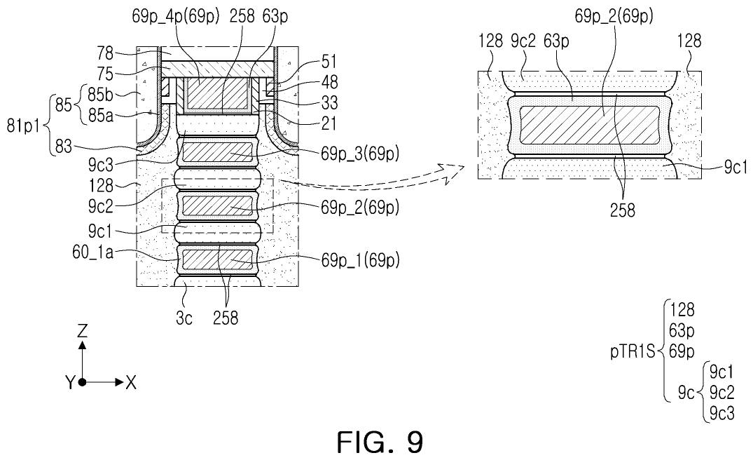

FIG. 9 is a partially enlarged cross-sectional view illustrating a modified portion from the partially enlarged view of FIG. 6A to explain an exemplary example of a semiconductor device according to an example embodiment of the present disclosure.

In an example embodiment, referring to FIG. 9, the first PMOS insulating oxide layer 158 (see FIG. 6A) described above may be replaced with a first PMOS insulating oxide layer 258 formed in a form in which the spacer portions 158_1a (see FIG. 6A) are omitted and the interfacial portions 158_1b (See FIG. 6A) remain. That is, the first PMOS insulating oxide layer 258 may replace the interfacial portions 158_1b of FIG. 6A. As the spacer portions 158_1a (see FIG. 6A) are omitted, a magnitude of the first PMOS gate electrode 69p may increase, thereby improving the electrical characteristics of a gate electrode of the PMOS transistor including the first PMOS gate electrode 69p. The first PMOS insulating oxide layer 258 may be disposed between the first PMOS gate dielectric layer 63p and the first PMOS channel layers 9c, and between the first PMOS gate dielectric layer 63p and the third active region 3c. Accordingly, the first PMOS gate dielectric layer 63p may be in contact with the first PMOS source/drain regions 128.

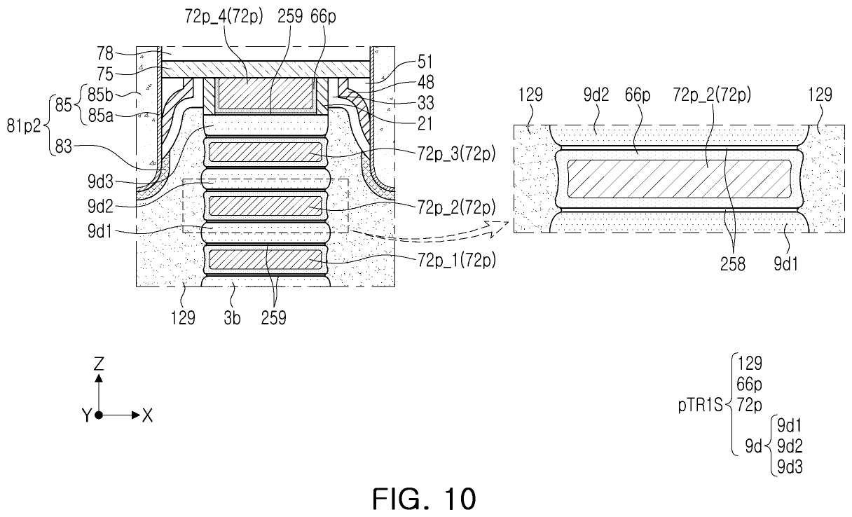

FIG. 10 is a partially enlarged cross-sectional view illustrating a modified portion of the partial enlarged view of FIG. 6B to explain an exemplary example of a semiconductor device according to an example embodiment of the present disclosure.

In an example embodiment, referring to FIG. 10, the second PMOS insulating oxide layer 59 (see FIG. 6B) described above may be replaced with a second PMOS insulating oxide layer 259 formed in a form in which the spacer portions 159_1a (see FIG. 6B) are omitted and the interfacial portions 159_1b (see FIG. 6B) remain. As the spacer portions 159_1a (see FIG. 6B) are omitted, a magnitude of the second PMOS gate electrode 72p may increase, thereby improving the electrical characteristics of the gate electrode of the PMOS transistor including the second PMOS gate electrode 72p. The second PMOS insulating oxide layer 259 may be disposed between the second PMOS gate dielectric layer 66p and the second PMOS channel layers 9d, and between the first PMOS gate dielectric layer 63p and the third active region 3c. Accordingly, the first PMOS gate dielectric layer 63p may be in contact with the first PMOS source/drain regions 128.

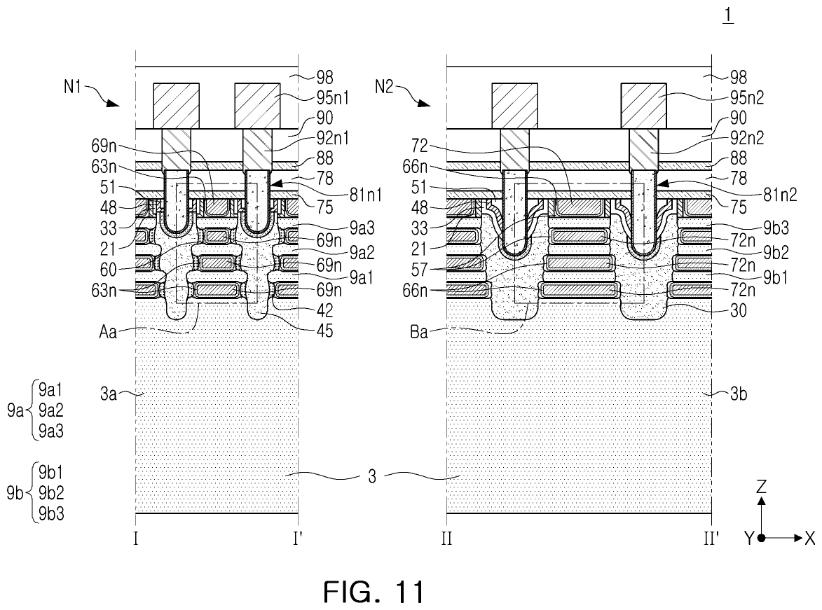

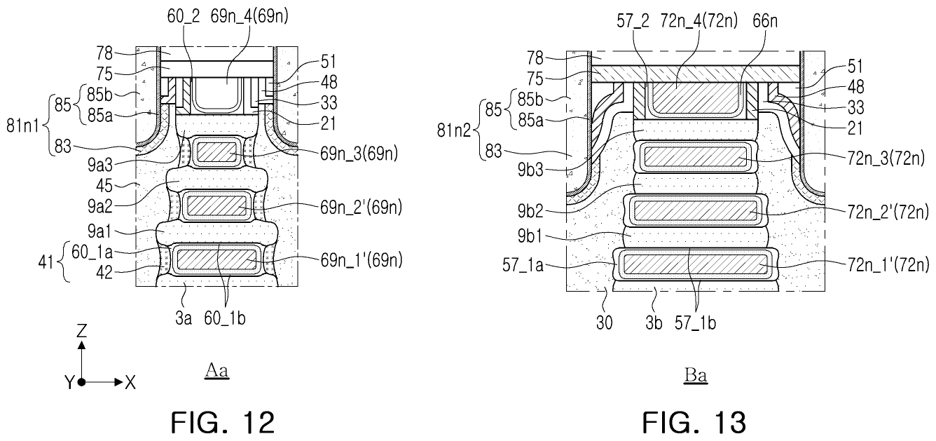

FIG. 11 is a cross-sectional view illustrating regions taken along the line I-I′ of FIG. 1A and the line II-II′ of FIG. 1B to explain an exemplary example of a semiconductor device according to an example embodiment of the present disclosure and may illustrate a portion modified in the cross-sectional view of FIG. 2. FIG. 12 is a partially enlarged view of a region indicated by ‘Aa’ of FIG. 11, and FIG. 13 is a partially enlarged view of a region indicated by ‘Ba’ of FIG. 11.

Referring to FIGS. 11, 12, and 13, in the first NMOS gate electrode 69n, the first NMOS intermediate gate portion 69n_2 (see FIG. 3A) described above may be modified into the first NMOS intermediate gate portion 69n_2′ in which a width thereof in the first horizontal direction (X-direction) increases, and the first NMOS lower gate portion 69n_1 (see FIG. 3A) described above may be modified into the first NMOS lower gate portion 69n_1′ in which a width thereof in the first horizontal direction (X-direction) increases.

In the first horizontal direction (X-direction), the first NMOS intermediate gate portion 69n_2′ may have a width greater than a width of the first NMOS upper gate portion 69n_3 described above, and the first NMOS lower gate portion 69n_1′ may have a width greater than a width of the first NMOS intermediate gate portion 69n_2′. Accordingly, an overall magnitude of the first NMOS gate electrode 69n may increase, thereby improving the electrical characteristics of the gate electrode of the NMOS transistor including the first NMOS gate electrode 69n.

In the second NMOS gate electrode 72n, the second NMOS intermediate gate portion 72n_2 (see FIG. 3B) described above may be modified into a second NMOS intermediate gate portion 72n_2′ in which a width thereof in the first horizontal direction (X-direction) increases, and the second NMOS lower gate portion 72n_1 (see FIG. 3B) described above may be modified into a second NMOS lower gate portion 72n_1′ in which a width thereof in the first horizontal direction (X-direction) increases.

In the first horizontal direction (X-direction), the second NMOS intermediate gate portion 72n_2′ may have a width greater than a width of the second NMOS upper gate portion 72n_3 described above, and the second NMOS lower gate portion 72n_1′ may have a width greater than a width of the second NMOS intermediate gate portion 72n_2′. Accordingly, an overall magnitude of the second NMOS gate electrode 72n may increase, thereby improving the electrical characteristics of the gate electrode of the NMOS transistor including the second NMOS gate electrode 72n.

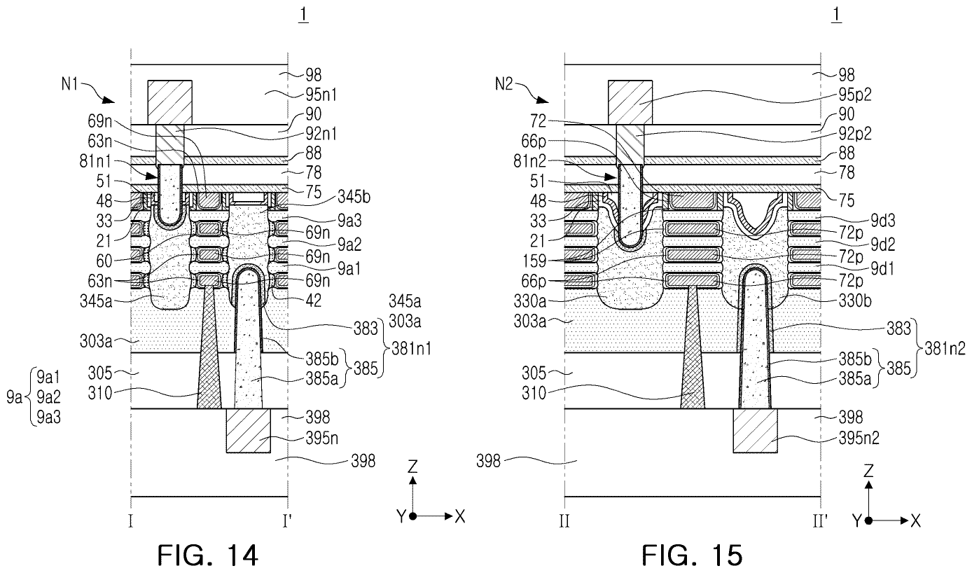

FIG. 14 is a cross-sectional view illustrating a region taken along the line I-I′ of FIG. 1A to explain an exemplary example of a semiconductor device according to an example embodiment of the present disclosure, and may illustrate a modified portion in the cross-sectional portion of the line I-I′ of FIG. 2, and FIG. 15 is a cross-sectional view illustrating a region taken along the line II-II′ of FIG. 1B to explain an exemplary example of a semiconductor device according to an example embodiment of the present disclosure, and may illustrate a modified portion in the cross-sectional portion of the line II-II′ of FIG. 2.

Referring to FIGS. 14 and 15, the first NMOS source/drain regions 45 (see FIGS. 2 and 3A) described above may be replaced with a first-first NMOS source/drain region 345a and a first-second NMOS source/drain region 345b spaced apart from each other in the first horizontal direction (X-direction). The second NMOS source/drain regions 30 (see FIGS. 2 and 3B) described above may be replaced with a second-first NMOS source/drain region 330a and a second-second NMOS source/drain region 330b spaced apart from each other in the first horizontal direction (X-direction).

The substrate 3, the first active region 3a and the second active region 3b described above in FIGS. 2, 3A and 3B may be replaced with a semiconductor substrate 303a having a reduced thickness. The semiconductor substrate 303a may be disposed below the first and second NMOS channel layers 9a and 9b, the first and second NMOS gate electrodes 69n and 72n, the first-first NMOS source/drain region 345a, the first-second NMOS source/drain region 345b, the second-first NMOS source/drain region 330a and the second-second NMOS source/drain region 330b.

The semiconductor device 1 may further include a first rear insulating layer 305 below the semiconductor substrate 303a, rear interconnection structures 395n1 and 395n2 disposed below the first rear insulating layer 305, and a second rear insulating layer 398 covering the rear interconnection structures 395n1 and 395n2 below the first rear insulating layer 305.

The semiconductor device 1 may further include insulating separation structures 310 penetrating through the first rear insulating layer 305 and the semiconductor substrate 303a. The insulating separation structures 310 may separate a portion of the semiconductor substrate 303a connected to the first-first NMOS source/drain region 345a and a portion of the semiconductor substrate 303a connected to the first-second NMOS source/drain region 345b, and may separate a portion of the semiconductor substrate 303a connected to the second-first NMOS source/drain region 330a and a portion of the semiconductor substrate 303a connected to the second-second NMOS source/drain region 330b.

At least one of the source/drain contact structures 81n1 (see FIG. 2 and FIG. 3A) connected to the first NMOS source/drain regions 45 (see FIG. 2 and FIG. 3A) described above, or at least one of the source/drain contact structures 81n2 (see FIG. 2 and FIG. 3B) connected to the second NMOS source/drain regions 30 (see FIG. 2 and FIG. 3B) described above, may be replaced by rear source/drain contact structures 381n1 and 381n2 penetrating through the first rear insulating layer 305 and the semiconductor substrate 303a. For example, at least one of the source/drain contact structures 81n1 (see FIGS. 2 and 3a) connected to the first NMOS source/drain regions 45 (see FIGS. 2 and 3A) may be replaced with a rear source/drain contact structure connected to at least one corresponding source/drain region, among the first-first NMOS source/drain regions 345a and the first-second NMOS source/drain regions 345b. For example, one of the source/drain contact structures 81n1 (see FIGS. 2 and 3A) may be electrically connected to the first-first NMOS source/drain region 345a in the same form as that of FIGS. 2 and 3A, and the other thereof may be replaced with a first rear source/drain contact structure 381n1 penetrating the first rear insulating layer 305 and the semiconductor substrate 303a, passing through a lower surface of the first-second NMOS source/drain region 345b and extending into the first-second NMOS source/drain region 345b. One of the source/drain contact structures 81n2 (see FIGS. 2 and 3B) may be electrically connected to the second-first NMOS source/drain region 330a in the same form as that of FIGS. 2 and 3B, and the other one thereof may be replaced with a second rear source/drain contact structure 381n2 penetrating the first rear insulating layer 305 and the semiconductor substrate 303a, passing through a lower surface of the second-second NMOS source/drain region 330b and extending into the second-second NMOS source/drain region 330b.

Each of the rear source/drain contact structures 381n1 and 381n2 may include a metal-semiconductor compound layer 383 and a source/drain contact plug 385 below the metal-semiconductor compound layer 383. The source/drain contact plug 385 may include a plug conductive pattern 385b and a conductive barrier layer 385a covering a side surface and an upper surface of the plug conductive pattern 385b. In each of the rear source/drain contact structures 381n1 and 381n2, the metal-semiconductor compound layer 383 may be in contact with a corresponding source/drain region, among the source/drain regions 345b and 330b, and a corresponding semiconductor substrate, among the semiconductor substrate 303a. The rear source/drain contact structures 381n1 and 381n2 may be electrically connected to the rear interconnection structures 395n1 and 395n2.

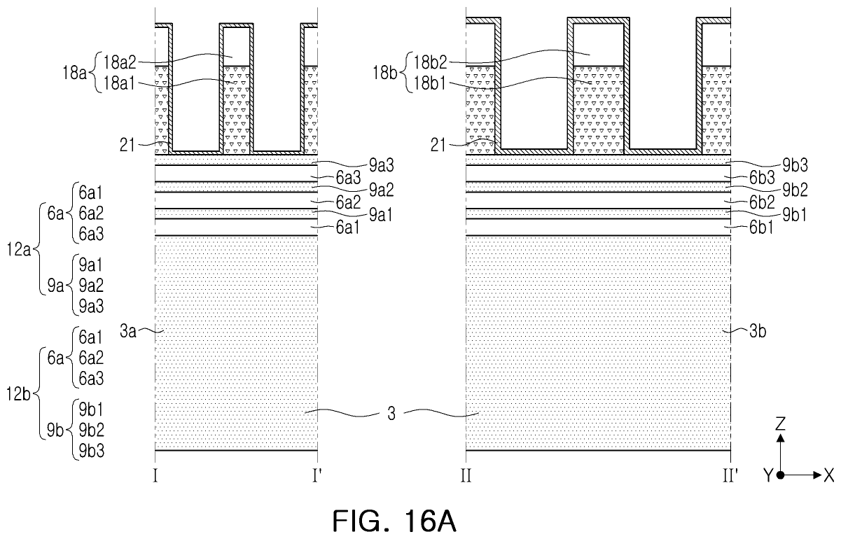

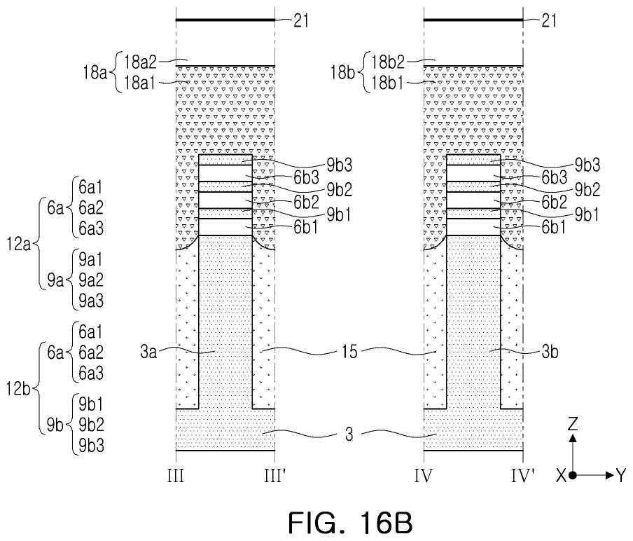

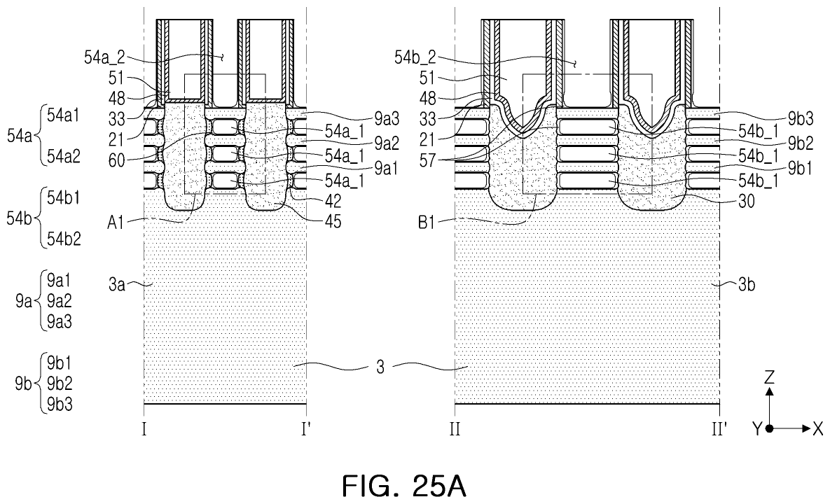

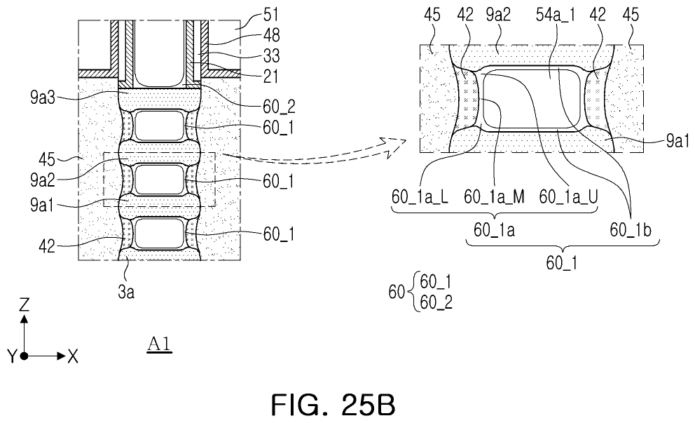

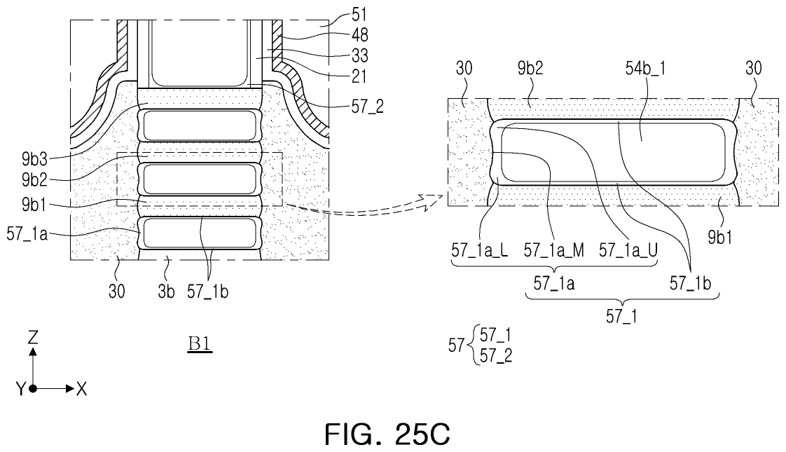

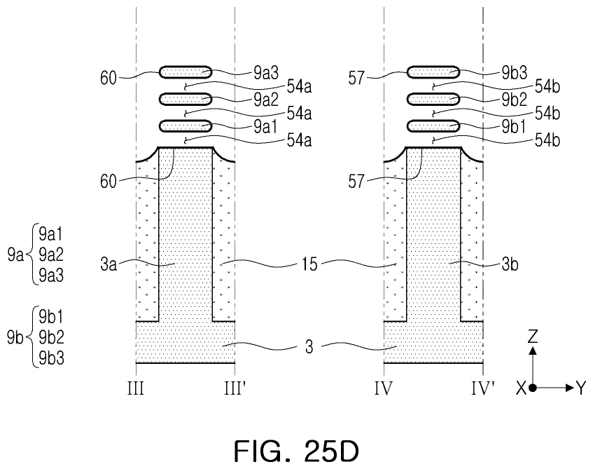

Next, with reference to FIGS. 16A, 16B, 17A, 17B, 18 to 23, 24A, 24B, 25A, 25B, 25C, 25D, 26A and 26B, an example of a forming method of a semiconductor device according to an example embodiment of the present disclosure will be described. For example, a forming method of the first NMOS insulating spacer structure 41 (see FIGS. 2 and 3A) and the second NMOS insulating spacer structure 57_1a (see FIGS. 2 and 3B) having different shapes and structures will be described. In FIGS. 16A, 16B, 17A, 17B, FIGS. 18 to 23, 24A, 24B, 25A, 25B, 25C, 25D, 26A and 26B, FIGS. 16A, 17A, 18 to 23, 24A, 25A and 26A are cross-sectional views illustrating regions taken along line I-I′ of FIG. 1A and line II-II′ of FIG. 1B, FIGS. 16B, 17B, 24B, 25D and 26B are cross-sectional views illustrating a region taken along line III-III′ of FIG. 1A and line IV-IV′ of FIG. 1B, FIG. 25B is a partially enlarged view illustrating a region indicated by ‘A1’ of FIG. 25A, and FIG. 25C is a partially enlarged view of a region indicated by ‘B1’ of FIG. 25A.

Referring to FIGS. 1A, 1B, 16A and 16B, a structure including a substrate 3, a device isolation region 15 defining active regions 3a on the substrate 3, and stack structures 12a and 12b on the active regions 3a may be prepared. The stack structures 12a and 12b may include a first stack structure 12a formed in a first NMOS region N1 and a second stack structure 12b formed in a second NMOS region N2. The first stack structure 12a may include first sacrificial semiconductor layers 6a and first channel layers 9a, which are alternately stacked. The second stack structure 12b may include stacked second sacrificial semiconductor layers 6b and second channel layers 9b, which are alternately stacked. The first sacrificial semiconductor layers 6a may include a first lower sacrificial semiconductor layer 6a1, a first intermediate sacrificial semiconductor layer 6a2 and a first upper sacrificial semiconductor layer 6a3, which are stacked while being spaced apart from each other in the vertical direction (Z-direction). The second sacrificial semiconductor layers 6b may include a second lower sacrificial semiconductor layer 6b1, a second intermediate sacrificial semiconductor layer 6b2 and a second upper sacrificial semiconductor layer 6b3, which are stacked while being spaced apart from each other in the vertical direction (Z-direction). The first channel layers 9a may include a first NMOS lower channel layer 9a1, a first NMOS intermediate channel layer 9a2, and a first NMOS upper channel layer 9a3 that are stacked while being spaced apart from each other in the vertical direction (Z-direction). The second channel layers 9b may include a second NMOS lower channel layer 9b1, a second NMOS intermediate channel layer 9b2 and a second NMOS upper channel layer 9b3, which are stacked while being spaced apart from each other in the vertical direction (Z-direction).

The first and second channel layers 9a and 9b may be formed of a first semiconductor material, such as silicon. The first and second sacrificial semiconductor layers 6a and 6b may be formed of a second semiconductor material, such as silicon-germanium, other than the first and second channel layers 9a and 9b.

Gate mask patterns 18a and 18b extending in the second horizontal direction (Y-direction) may be formed. The gate mask patterns 18a and 18b may be formed on the stack structures 12a and 12b and the device isolation region 15. The gate mask patterns 18a and 18b may include a first NMOS mask pattern 18a formed within the first NMOS region N1, and a second NMOS mask pattern 18b formed within the second NMOS region N2.

The first NMOS mask pattern 18a may extend by intersecting the first stack structure 12a in the second horizontal direction (Y-direction), and the second NMOS mask pattern 18b may extend by intersecting the second stack structure 12b in the second horizontal direction (Y-direction).

The first NMOS mask pattern 18a may include a first lower mask layer 18a1 and a first upper mask layer 18a2, which are sequentially stacked, and the second NMOS mask pattern 18b may include a second lower mask layer 18b1 and a second upper mask layer 18b2, which are sequentially stacked.

A first insulating liner 21 conformally covering the stack structures 12a and 12b and the gate mask patterns 18a and 18b may be formed.

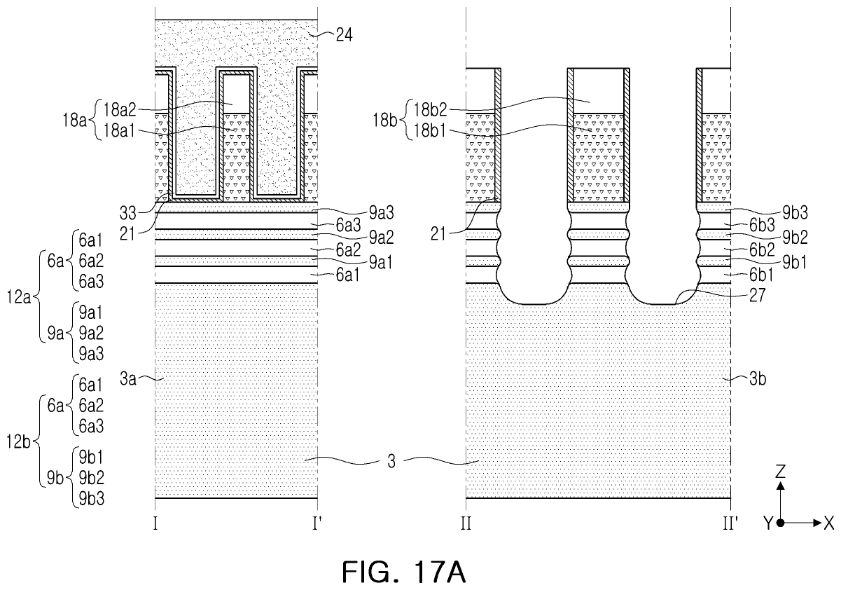

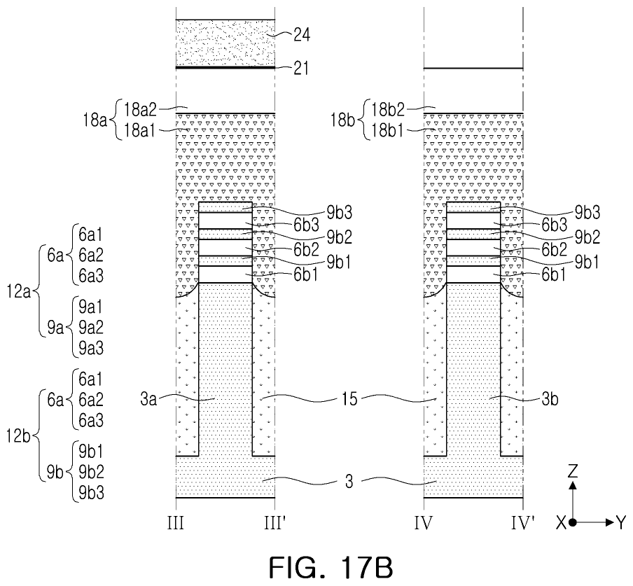

Referring to FIGS. 1A, 1B, 17A and 17B, a first protective mask 24 covering the first insulating liner 21 may be formed on the first NMOS region N1. In a state in which the first NMOS region N1 is protected by the first protective mask 24, the first insulating liner 21 of the second NMOS region N2 may be anisotropically etched, and then the second stack structure 12b may be etched, thereby forming recesses 27 penetrating through the second stack structure 12b.

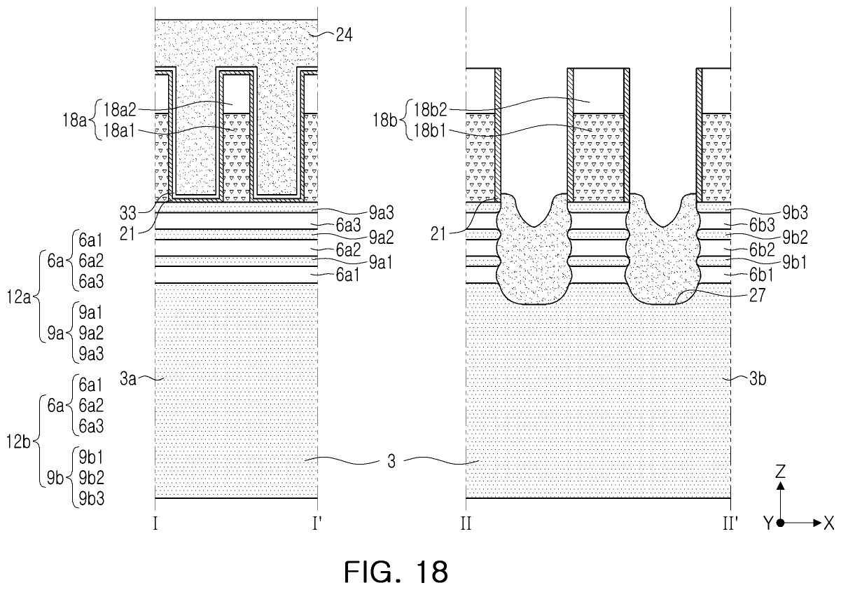

Referring to FIGS. 1A, 1B and 18, in a state in which the first NMOS region N1 is protected by the first protective mask 24, a second NMOS source/drain epitaxial growth process may be performed, thereby forming second NMOS source/drain regions 30 formed by epitaxial growth from the active region 3b exposed by the recesses 27, side surfaces of the second sacrificial semiconductor layers 6b and side surfaces of the second channel layers 9b. Each of the second NMOS source/drain regions 30 may have an upper surface having a shape in which a central portion is recessed.

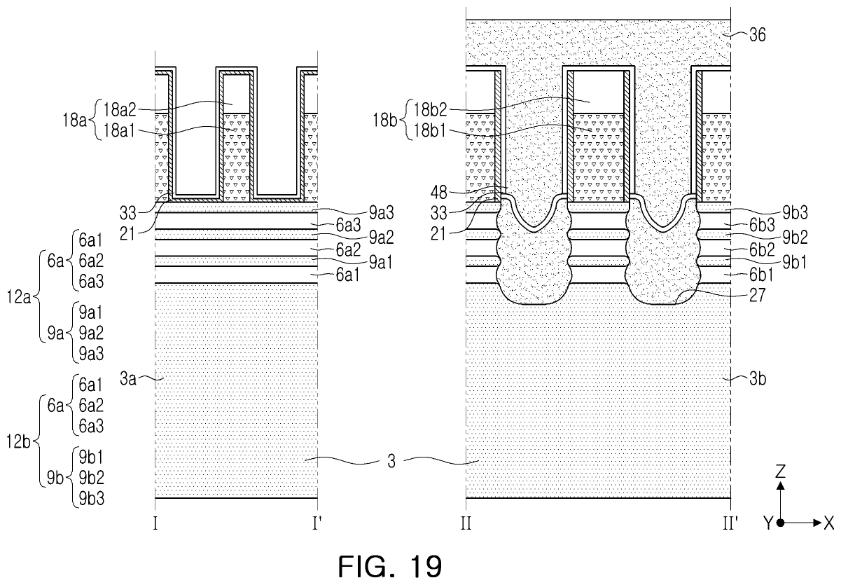

Referring to FIGS. 1A, 1B and 19, the first protective mask 24 (see FIG. 18) may be removed. Next, a second insulating liner 33 conformally covering the first insulating liner 21 and the second NMOS source/drain regions 30 may be formed. A second protective mask 36 covering the second insulating liner 33 may be formed on the second NMOS region N2.

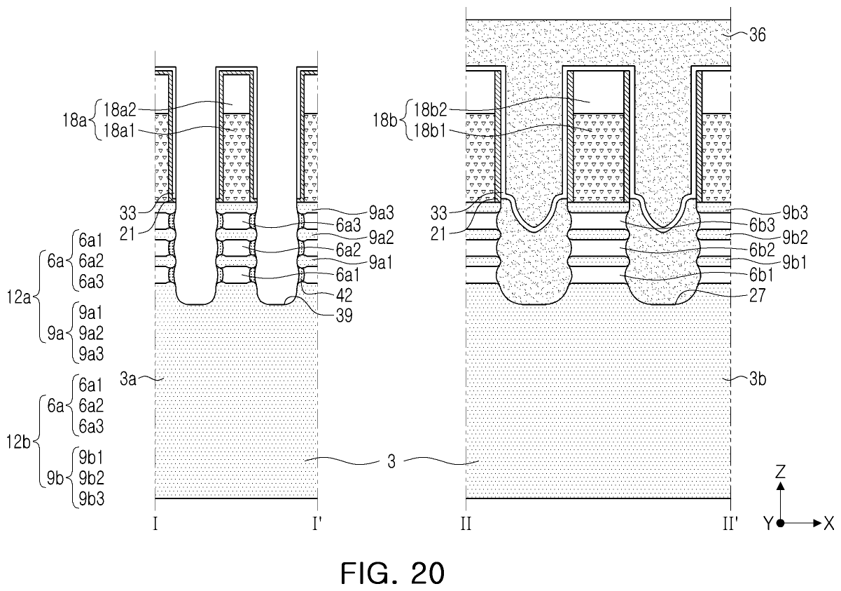

Referring to FIGS. 1A, 1B and 20, in a state in which the second NMOS region N2 is protected by the second protective mask 36, the first and second insulating liners 21 and 33 of the first NMOS region N1 may be anisotropically etched, and then the first stack structure 12a may be etched, thereby forming recesses 39 penetrating through the first stack structure 12a.

Side surfaces of the first sacrificial semiconductor layers 6a exposed by the recesses 39 may be further recessed than side surfaces of the first channel layers 9a exposed by the recesses 39. Then, insulating spacer patterns 42 formed below each of the first channel layers 9a in contact with the side surfaces of the first sacrificial semiconductor layers 6a may be formed. The insulating spacer patterns 42 may be formed of silicon nitride.

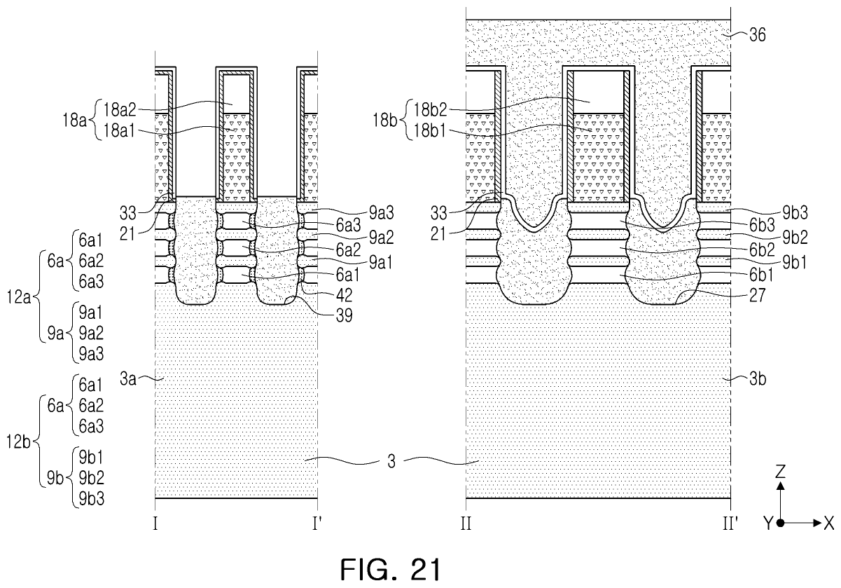

Referring to FIGS. 1A, 1B and 21, in a state in which the second NMOS region N2 is protected by the second protective mask 36, the first NMOS source/drain epitaxial growth process may be performed, thereby forming the first NMOS source/drain regions 45 formed by epitaxial growth from the active region 3a and the first channel layers 9a exposed by the recesses 39.

Since the first NMOS source/drain regions 45 have a relatively small width, even if the first NMOS source/drain regions 45 are epitaxially grown from the active region 3a and the first channel layers 9a exposed by the recesses 39, the first NMOS source/drain regions 45 may be formed without defects.

The second NMOS source/drain regions 30 described in the above-described FIG. 18 have a larger width than that of the first NMOS source/drain regions 45, but since the second NMOS source/drain regions 30 are formed by epitaxial growth from the active region 3b exposed by the recesses 27, the side surfaces of the second sacrificial semiconductor layers 6b and the side surfaces of the second channel layers 9b, the second NMOS source/drain regions 30 may thus be formed without defects.

According to example embodiments, the first NMOS source/drain regions 45 and the second NMOS source/drain regions 30 may be formed reliably without defects.

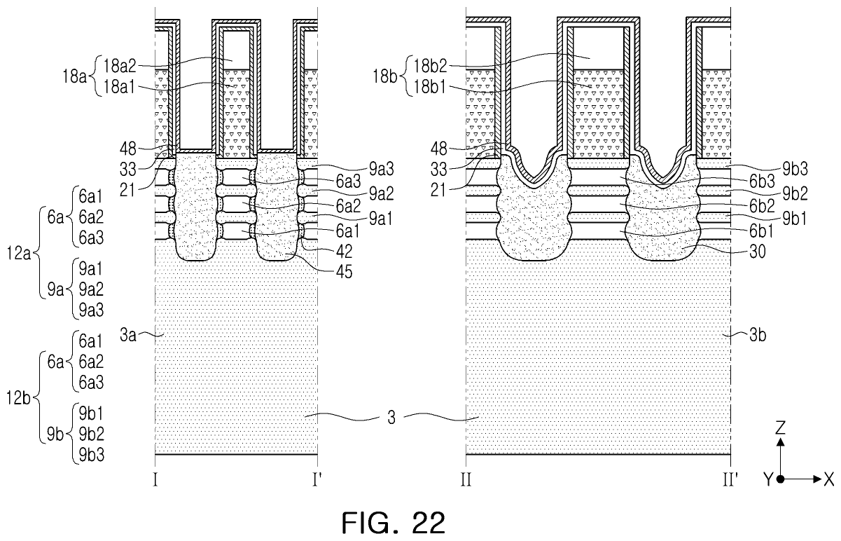

Referring to FIGS. 1A, 1B and 22, the second protective mask 36 (see FIG. 21) may be removed. Subsequently, a third insulating liner 48 conformally covering the first NMOS source/drain regions 45 and the second insulating liner 33 may be formed.

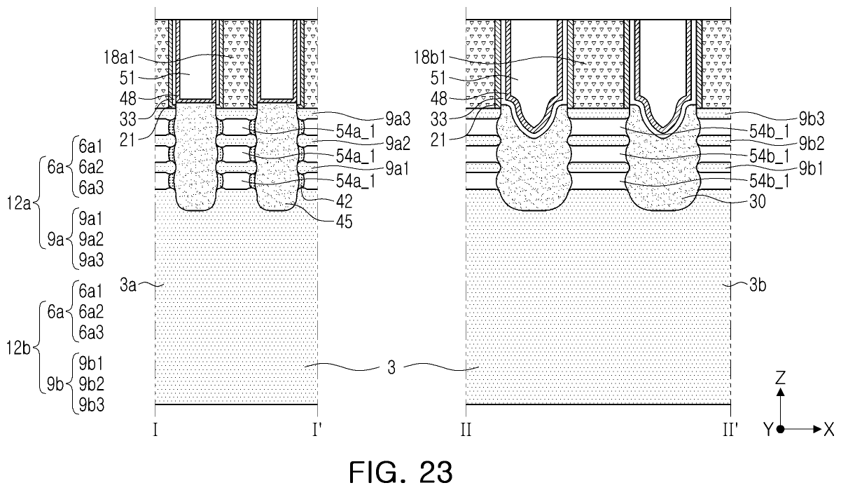

Referring to FIGS. 1A, 1B and 23, an interlayer insulating layer 51 may be formed on the third insulating liner 48. A planarization process may be performed until the first and second lower mask layers 18a1 and 18b1 are exposed. The first and second upper mask layers 18a2 and 18b2 (see FIG. 22) may be removed by the planarization process, and the interlayer insulating layer 51 may remain on side surfaces of the first and second lower mask layers 18a1 and 18b1 on the third insulating liner 48.

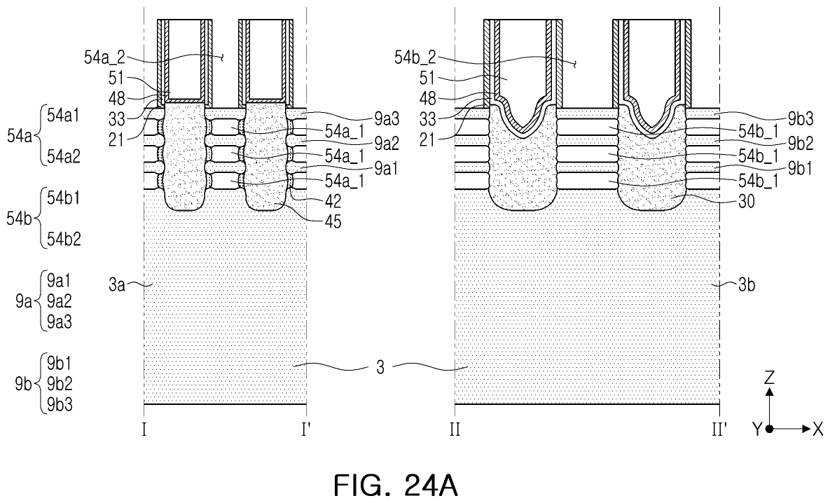

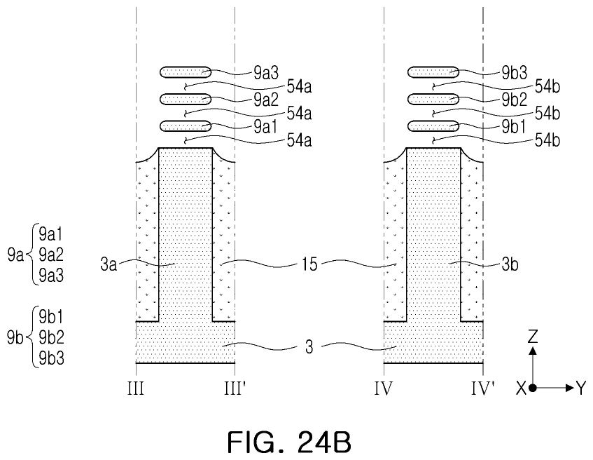

Referring to FIGS. 1A, 1B, 24A and 24B, the first and second lower mask layers 18a1 and 18b1 (see FIG. 23) and the first and second sacrificial semiconductor layers 6a and 6b (see FIG. 23) may be removed to simultaneously form the first opening 54a and the second opening 54b.

The first opening 54a may include a first upper opening 54a_2 formed by removing the first lower mask layer 18a1 and first lower openings 54a_1 formed by removing the first sacrificial semiconductor layers 6a. The second opening 54b may include a second upper opening 54b_2 formed by removing the second lower mask layer 18b1 and second lower openings 54b_1 formed by removing the second sacrificial semiconductor layers 6b.

The first lower openings 54a_1 may expose the insulating spacer patterns 42, and the second lower openings 54b_1 may expose the second NMOS source/drain regions 30.

Referring to FIGS. 1A, 1B, 25A, 25B, 25C and 25D, insulating oxide layers 57 and 60 may be formed. Forming the insulating oxide layers 57 and 60 may include forming a preliminary oxide layer conformally covering internal inner walls of each of the first and second openings 54a and 54b, advancing a process of densifying at least a portion of the preliminary oxide layer, and etching the densified preliminary oxide layer so as to remain more thickly on corners of the openings 54 and 54b and sidewalls of the lower openings 54a_1 and 54b_1. The insulating oxide layers 57 and 60 may include a first NMOS insulating oxide layer 60 formed on an internal wall of the first opening 54a and a second NMOS insulating oxide layer 57 formed on the internal wall of the first opening 54a.

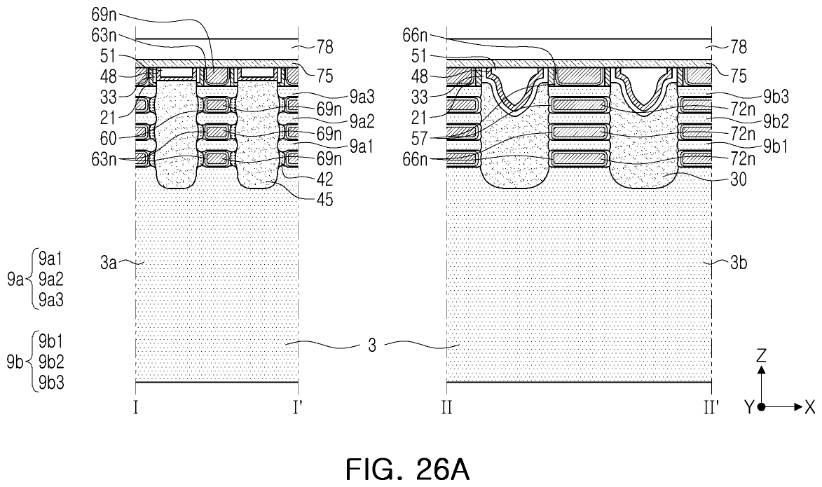

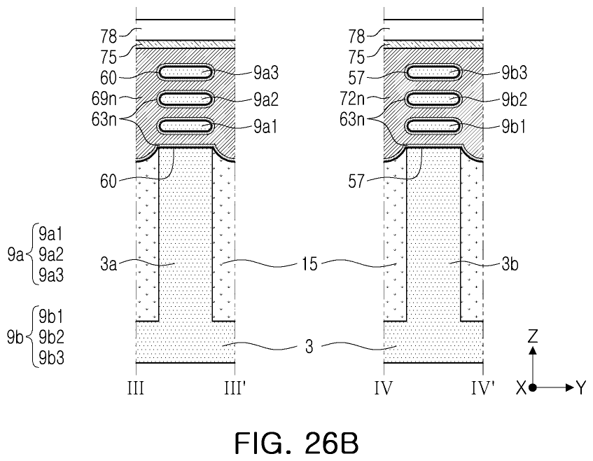

Referring to FIGS. 1A, 1B, 26A and 26B, gate dielectric layers 63n and 66n conformally covering the first and second openings 54a and 54b on which the insulating oxide layers 57 and 60 are formed on inner walls thereof may be formed. A conductive material filling the first and second openings 54a and 54b covered with the gate dielectric layers 63n and 66n may be formed, and gate electrodes 69n and 72n may be formed by planarizing the conductive material. By the process of planarizing the conductive material to form the gate electrodes 69n and 72n, the interlayer insulating layers 51 and the insulating liners 21, 33 and 48 may be formed to have upper surfaces coplanar with upper surfaces of the gate electrodes 69n and 72n.

Next, by performing contact and wiring processes, source/drain contact structures 81n1, 81n2, 81p1 and 81p2, gate contact structures 93n1, 93n2, 93p1 and 93p2, and interconnection structures 95n1, 95n2, 95p1, 95p2, 96n1, 96n2, 96p1 and 96p2 as in FIG. 2, FIG. 3A, FIG. 3B, FIG. 4, FIG. 5, FIG. 6A and FIG. 6B may be formed.

Although example embodiments of the present disclosure have been described with reference to the accompanying drawings, it will be understood by those skilled in the art that the present disclosure may be implemented in other specific forms without changing its technical concepts or essential features. Therefore, it should be understood that the example embodiments described above are by way of example not limited in all respects.

What is claimed is:

1. A semiconductor device, comprising:
a first NMOS transistor structure; and
a second NMOS transistor structure,
wherein the first NMOS transistor structure comprises:
a first NMOS source/drain region;
first NMOS channel layers stacked and spaced apart from each other, and electrically connected to the first NMOS source/drain region in a first direction;
a first NMOS gate electrode surrounding each of the first NMOS channel layers in a second direction crossing the first direction;
a first NMOS gate dielectric layer between the first NMOS gate electrode and the first NMOS channel layers, and between the first NMOS gate electrode and the first NMOS source/drain region; and
a first NMOS insulating spacer structure between the first NMOS gate dielectric layer and the first NMOS source/drain region,
wherein the second NMOS transistor structure comprises:
a second NMOS source/drain region;
second NMOS channel layers stacked and spaced apart from each other, and electrically connected to the second NMOS source/drain region in the first direction;
a second NMOS gate electrode extending in the second direction, and surrounding each of the second NMOS channel layers in the second direction;
a second NMOS gate dielectric layer between the second NMOS gate electrode and the second NMOS channel layers, and between the second NMOS gate electrode and the second NMOS source/drain region; and
a second NMOS insulating spacer structure between the second NMOS gate dielectric layer and the second NMOS source/drain region,
wherein the first NMOS insulating spacer structure comprises a first NMOS insulating spacer pattern, and
wherein the second NMOS insulating spacer structure comprises a second NMOS insulating oxide layer and does not comprise an insulating spacer pattern identical to the first NMOS insulating spacer pattern.

2. The semiconductor device of claim 1, wherein a width of a second NMOS channel layer in the first direction, among the second NMOS channel layers, is greater than a width of a first NMOS channel layer in the first direction, among the first channel layers, the first NMOS channel layer being coplanar with the second NMOS channel layer.

3. The semiconductor device of claim 1, wherein a maximum width of the second NMOS source/drain region in the first direction is greater than a maximum width of the first NMOS source/drain region in the first direction.

4. The semiconductor device of claim 1, wherein each of the first and second NMOS gate dielectric layers comprises a high-κ dielectric layer, and
wherein the high-κ dielectric layer has a dielectric constant higher than a dielectric constant of silicon oxide.

5. The semiconductor device of claim 4, wherein the second NMOS insulating oxide layer is a dielectric having a lower dielectric constant than a dielectric constant of the high-κ dielectric layer of the second NMOS gate dielectric layer.

6. The semiconductor device of claim 4, wherein the insulating spacer pattern comprises silicon nitride, and
wherein the second NMOS insulating oxide layer comprises silicon oxide.

7. The semiconductor device of claim 1, wherein a minimum thickness of the first NMOS insulating spacer pattern is greater than a minimum thickness of the second NMOS insulating oxide layer.

8. The semiconductor device of claim 1, wherein the second NMOS transistor structure further comprises:
an interfacial oxide layer extending from the second NMOS insulating oxide layer and between the second NMOS channel layers and the second NMOS gate dielectric layer.

9. The semiconductor device of claim 1, wherein the first NMOS insulating spacer structure further comprises a first NMOS insulating oxide layer between the insulating spacer pattern and the first NMOS gate dielectric layer.

10. The semiconductor device of claim 9, wherein a minimum thickness of the first NMOS insulating spacer pattern is greater than a minimum thickness of the first NMOS insulating oxide layer.

11. The semiconductor device of claim 9, further comprising:
a first interfacial oxide layer extending from the first NMOS insulating oxide layer of the and between the first NMOS channel layers and the first NMOS gate dielectric layer.

12. The semiconductor device of claim 1, further comprising:
a first contact structure electrically connected to the first NMOS source/drain region; and
a second contact structure electrically connected to the second NMOS source/drain region.

13. A semiconductor device, comprising:
a first NMOS transistor structure; and
a second NMOS transistor structure,
wherein the first NMOS transistor structure comprises:
a first NMOS source/drain region;
first NMOS channel layers stacked and spaced apart from each other, and electrically connected to the first NMOS source/drain region in a first direction;
a first NMOS gate electrode extending in a second direction, crossing the first direction, and surrounding each of the first NMOS channel layers in the second direction;
a first NMOS gate dielectric layer between the first NMOS gate electrode and the first NMOS channel layers, and between the first NMOS gate electrode and the first NMOS source/drain region; and
a first NMOS insulating spacer structure between the first NMOS gate dielectric layer and the first NMOS source/drain region,
wherein the second NMOS transistor structure comprises:
a second NMOS source/drain region;
second NMOS channel layers stacked and spaced apart from each other, and electrically connected to the second NMOS source/drain region in the first direction;
a second NMOS gate electrode extending in the second direction, and surrounding each of the second NMOS channel layers in the second direction;
a second NMOS gate dielectric layer between the second NMOS gate electrode and the second NMOS channel layers, and between the second NMOS gate electrode and the second NMOS source/drain region; and
a second NMOS insulating spacer structure between the second NMOS gate dielectric layer and the second NMOS source/drain region,
wherein the first NMOS channel layers comprise a first NMOS lower channel layer, a first NMOS intermediate channel layer on the first NMOS lower channel layer, and a first NMOS upper channel layer on the first NMOS intermediate channel layer,
wherein the second NMOS channel layers comprise a second NMOS lower channel layer, a second NMOS intermediate channel layer on the second NMOS lower channel layer, and a second NMOS upper channel layer on the second NMOS intermediate channel layer,
wherein the first NMOS gate electrode comprises:
a first NMOS lower gate portion directly below the first NMOS lower channel layer;
a first NMOS intermediate gate portion directly below the first NMOS intermediate channel layer; and
a first NMOS upper gate portion directly below the first NMOS upper channel layer,
wherein the second NMOS gate electrode comprises:
a second NMOS lower gate portion directly below the second NMOS lower channel layer;
a second NMOS intermediate gate portion directly below the second NMOS intermediate channel layer; and
a second NMOS upper gate portion directly below the second NMOS upper channel layer,
wherein the first NMOS insulating spacer structure comprises a first NMOS intermediate spacer portion between the first NMOS source/drain region and the first NMOS intermediate gate portion,
wherein the second NMOS insulating spacer structure comprises a second NMOS intermediate spacer portion between the second NMOS source/drain region and the second NMOS intermediate gate portion,
wherein a thickness of the first NMOS intermediate spacer portion is greater than a thickness of the second NMOS intermediate spacer portion,
wherein the thickness of the second NMOS intermediate spacer portion is a thickness perpendicular to a surface of the second NMOS gate dielectric layer in contact with the second NMOS intermediate spacer portion of the second NMOS gate dielectric layer, and
wherein the thickness of the first NMOS intermediate spacer portion is a thickness perpendicular to a surface of the first NMOS gate dielectric layer in contact with or facing the first NMOS intermediate spacer portion of the first NMOS gate dielectric layer.

14. The semiconductor device of claim 13, wherein the second NMOS insulating spacer structure extends from between the second NMOS gate dielectric layer and the second NMOS source/drain region to between the second NMOS gate dielectric layer and the second NMOS channel layers.

15. The semiconductor device of claim 13, wherein a width of the second NMOS lower channel layer in the first direction is greater than a width of the first NMOS lower channel layer in the first direction.

16. The semiconductor device of claim 13, wherein a maximum width of the second NMOS source/drain region in the first direction is greater than a maximum width of the first NMOS source/drain region in the first direction.

17. A semiconductor device, comprising:
a first NMOS transistor structure; and
a second NMOS transistor structure,
wherein the first NMOS transistor structure comprises:
first NMOS channel layers spaced apart from each other in a first direction;
a first NMOS source/drain region electrically connected to the first NMOS channel layers in a second direction perpendicular to the first direction;
a first NMOS gate electrode comprising a first NMOS intermediate electrode portion between the first NMOS channel layers;
a first NMOS gate dielectric layer between the first NMOS gate electrode and the first NMOS channel layers; and
a first NMOS insulating spacer structure between the first NMOS intermediate electrode portion and the first NMOS source/drain region, and
wherein the second NMOS transistor structure comprises:
second NMOS channel layers spaced apart from each other in the first direction;
a second NMOS source/drain region connected to the second NMOS channel layers in the second direction;
a second NMOS gate electrode comprising a second NMOS intermediate electrode portion between the second NMOS channel layers;
a second NMOS gate dielectric layer between the second NMOS gate electrode and the second NMOS channel layers; and
a second NMOS insulating spacer structure between the second NMOS intermediate electrode portion and the second NMOS source/drain region,
wherein the first NMOS insulating spacer structure comprises an insulating spacer pattern, and
wherein the second NMOS insulating spacer structure comprises a second NMOS insulating oxide layer and does not include an insulating spacer pattern identical to the insulating spacer pattern.

18. The semiconductor device of claim 17, wherein in the second direction, a width of the second NMOS source/drain region is greater than a width of the first NMOS source/drain region,
the first NMOS gate dielectric layer extends between the first NMOS intermediate electrode portion and the first NMOS insulating spacer structure, and
the second NMOS gate dielectric layer extends between the second NMOS intermediate electrode portion and the second NMOS insulating spacer structure.

19. The semiconductor device of claim 18, wherein the first NMOS insulating spacer structure further comprises a first NMOS insulating oxide layer between the insulating spacer pattern and the first NMOS gate dielectric layer.

20. The semiconductor device of claim 17, wherein each of the first and second NMOS gate dielectric layers comprises a high-κ dielectric material,
wherein a dielectric constant of the high-κ dielectric material is higher than a dielectric constant of silicon oxide, and
wherein the second NMOS insulating oxide layer has a dielectric constant lower than the dielectric constants of the high-κ dielectric material of the second NMOS gate dielectric layer.
